(19) United States
(12) Patent Application Publication
(10) Pub. No.: US 2013/0228205 A1
(43) Pub. Date: Sep. 5, 2013

(54) Apparatus for reversibly converting thermal energy to electric energy

(71) Applicants: Yury Vernikovskiy, Moscow (RU); Sergey Streletskiy, Moscow (RU)

(72) Inventors: Yury Vernikovskiy, Moscow (RU); Sergey Streletskiy, Moscow (RU)

(21) Appl. No.: 13/374,965

(22) Filed: Jan. 25, 2012

Related U.S. Application Data
(60) Provisional application No. 61/436,090, filed on Jan. 25, 2011.
(60) Provisional application No. 61/469,794, filed on Mar. 30, 2011.

(51) Int. Cl. H01L 35/30; F25B 21/04

(52) U.S. Cl. CPC H01L 35/30; F25B 21/04
USPC 136/205; 62/3.3

(57) ABSTRACT

A thermoelectric device (the TED) of the present invention is used as a generator application and a heat pump application. The TED transfers heat from one side of the device to the other side from cold to hot, with consumption of electrical energy. In a functioning mode of the TED, direct current runs through the TED and heat is moved from one side of the TED to another side of the TED, wherein the TED is used either for heating or for cooling applications, generation of electricity and/or transfer of heat in heating and refrigerating applications.

### RELATED APPLICATIONS

This application claims priority to a provisional application Ser. No. 61/436,090 filed on Jan. 25, 2011 and a provisional application Ser. No. 61/469,794 filed on Mar. 30, 2011 and incorporated herewith by reference in its entirety.

### FIELD OF INVENTION

This invention pertains generally to the field of heat transfer devices, which transfers heat from one side of the device to the other side from cold to hot, with consumption of electrical energy, wherein direct current runs through the device and heat is moved from one side of the device to another side of the device, wherein the device is used either for heating or for cooling applications, generation of electricity and/or transfer of heat in heating and refrigerating applications.

### BACKGROUND OF THE INVENTION

The thermoelectric effect (TE) is the direct conversion of temperature differences to electric voltage and vice versa. A thermoelectric device creates a voltage when it is supplied with different temperatures on each side thereof. Conversely, when a voltage is applied to the device, it creates a temperature difference. This effect can be used, for example, to generate electricity, measure temperature, and heat or cool objects.

The conversion of energy from thermal state to electrical state (the thermoelectric phenomenon) has been described in view of Seebeck effect, the Peltier effect and the Thomson effect. The Thomson effect occurs in a conductor when the ends of that conductor are at different temperatures and an electric current is flowing, generating a heating that is different than I.sup.2R heating, the difference being dependent on the magnitude and direction of the current, the temperature, and on the material. The Peltier effect describes the isothermal heat exchange that takes place at the junction of two different materials when an electrical current flows between them. The rate of development of heat is greater or less than that of I.sup.2R heating, the difference depending upon the direction and magnitude of the electric current, on the temperature, and on the two materials forming the junction. The Seebeck effect can be viewed as the sum of the Peltier and Thomson effects around a circuit loop.

The Peltier effect is caused by the fact that the electron's average energy varies from material to material. Thus, when a charged carrier such as an electron or a hole crosses from one material to another, the charged carrier compensates for the energy difference by exchanging heat with the surrounding lattice. The amount of heat exchanged for a given current I across a junction is determined by the Peltier coefficient. The Peltier coefficient is negative if heat is transported by the electrons and it is positive if heat is transported by holes.

Thus, when a semiconductor material is placed between a heat source and a heat sink, a favorable current flow through the semiconductor causes the heat to be extracted from the heat source and deposited on the heat sink. Applying these principles, conventional systems have been devised to provide solid state cooling, typically for electronic devices. However, conventional systems and thermoelectric modules have been inefficient in their capacity to conduct heat.

Alluding to the above, in the conventional thermoelectric module, two dissimilar elements with a P-type and an N-type conductivity are interconnected by commutating copper plates and enclosed between two flat ceramic plates. The ceramic plates are made on the basis of aluminum oxide or aluminum nitride. The heat is delivered to one end and removed from the other. In the thermoelectric modules, a thermal current is interrupted by insulating layer of considerable thickness (ceramic plates based on aluminum oxide or aluminum nitride with anisotropic thermal conductivity). The thermal conductivity of the layer is significantly lower than the one that electricity conductors have. Thus, the thermal barrier created on the insulation layer prevents the seamless passage of heat through the thermoelectric semiconductor. Moreover, this layer is in contact with the adjacent surfaces, which also causes the loss of heat conductivity at the spots of the contacts.

The thermoelectric modules that deploy a contact between a bus-bar and the pellets done by soldering using low active rosin fluxes with minimum ion component concentrations for enhanced corrosion resistance of modules already exist. This design however has serious complications. The soldered contact is a rigid mechanical connection. Not only does it position pellets, but it also serves as a thermoelectric conductor between a bus-bar and the pellets, and provides the structural strength of the module as a whole unit. Since the modern soldered modules operate at a significant temperature difference between their working surfaces, especially for cyclic applications, they are a subject of a thermal stress, especially at the periphery of the module. This reduces the allowable operating temperature difference, accelerates the aging process of the module (the damage and cracking of pellets) and limits the size of both the pellets and the module as a whole unit.

The prior art is replete with various thermoelectric modules used in various thermoelectric applications taught by U.S. Pat. No. 5,409,547 to Watanabe et al., U.S. Pat. No. 6,034,317 to Watanabe et al., U.S. Pat. No. 6,038,865 to Watanabe et al., U.S. Pat. No. 7,687,705 to Ila, and U.S. Pat. No. 7,816,601 to Carver. Some of the prior art thermoelectric modules contain the following pellets: bismuth telluride (Bi2Te3) crystals (pellets) of the P- and N-types. The dimension of the crystals: cross section from 0.35×0.35 mm to 2.4×2.4 mm, height 0.3÷5 mm, bismuth telluride (Bi2Te3) crystals (pellets) of the P- and N-type of conductivity with metal coating for thermoelectric cooling modules. The dimension of the crystals (length, width and height)—1.4×1.4×1.6 mm, bismuth telluride (Bi2Te3) crystals (pellets) of the P- and N-type conductivity for thermoelectric generator modules. The dimension of the crystals: the cross section of 5×5 mm, and bismuth telluride (Bi2Te3) crystals (pellets) of the P- and N-types. The dimension of the crystals: the cross-section from 0.8×0.8 mm to 2.5×2.5 mm.

These small pellets that are used in the modern thermoelectric modules can be mass produced by sawing washers, derived from slabs. Due to a specific rectangular shape of the pellets and considerable width of a cut, a significant part of the thermoelectric material ends up in waste. Based on the analysis of the design, technological features and operating conditions of thermoelectric modules, the pellets are the “weakest” link in the module design due to the structural properties of thermoelectric materials based on bismuth telluride (Bi2Te3), as well as compression and tension mechanical tests for the pellets. The tests showed that the samples have high structural heterogeneity based on differences in thickness and length of the grains. These differences are also observed between various areas of samples plates. There is a difference in the crystallographic orientation of grains, which can be noticed in the macro volumes, as well as the presence of the fragmentation of grains, and possibly pores between fragments. This, in turn, explains a significant spread of the mechanical characteristics of semiconductor pellets. The structural heterogeneity of the thermoelectric material and the spread of mechanical characteristics of the pellets negatively affect the operating stability and physical and mechanical properties of the pellets. As a result, the reliability of the thermoelectric module suffers significantly.

Alluding to the above, numerous other prior art thermoelectric devices, both thermoelectric generators and heat pumps currently exist. Typical thermoelectric generator comprising at least one thermoelectric module with a receiving surface of the infrared radiation and whose cold side is cooled down by a liquid. A typical thermoelectric generator, comprising at least one thermoelectric module whose hot side is heated up and cold side is cooled down by a liquid. A typical thermoelectric generator, comprising at least one thermoelectric module that has thermoelectric conductors with the receiving surface of the infrared radiation and thermoelectric conductors cooled down by a gaseous medium. A heat pump comprising at least one thermoelectric module with heat exchangers, some of which are conjugated with a circuit of one heat carrier, and others—with a circuit of another heat carrier. A heat pump comprising at least one thermoelectric module with a heat exchanger conjugated with a circuit of a liquid heat carrier and another heat exchanger that is conjugated with a gaseous medium.

All aforementioned generators and heat pumps have deficiencies that can be explained by the shortcoming of their thermoelectric modules that have a classical design. Therefore, there is an opportunity and a constant need for improved thermoelectric devices with increased reliability, efficiency and technological simplicity in design that will eliminate all deficiencies and drawbacks of the prior art applications and designs.

### SUMMARY OF THE INVENTION

A thermoelectric assembly (the assembly) of the present invention pertains generally to the field of heat transfer devices, which transfers heat from one side of the device to the other side from cold to hot, with consumption of electrical energy, wherein direct current runs through the device and heat is moved from one side of the device to another side of the device, wherein the device is used either for heating or for cooling applications, generation of electricity and/or transfer of heat in heating and refrigerating applications.

The apparatus of the present invention includes at least one frame with a plurality of rails forming a plurality of void portions. A resilient element is connected to each of the rails. A source of fluid supply is connected to the apparatus. A plurality of collectors for receiving and circulating fluid are part of the apparatus. A plurality of thermoelectric conductors of hot and cold types alternating with one another are fluidly communicated with the collectors movable with the thermoelectric conductors to receive and circulate fluid. Each thermoelectric conductor presents a wedge like configuration having a peripheral surface and a pair of inclined surfaces and a pair of side surfaces.

The thermoelectric conductors are disposed inside the void portions between the rails and present a plurality of active layers of N-type conductivity and P-type conductivity. Each active layer includes a thickness being at least three times less than a length with each of the active layers positioned between and sandwiched by each of the thermoelectric conductors. Each active layer presents a core portion surrounded by an elastic element. The interconnecting layers are formed from at least one of deformable substance of electro and thermo conductivity and a solder having a melting temperature point below operating temperature and spreadable along the active layers and connected to the thermoelectric conductors. The deformable substance is further defined by a soft paste-like material spreadable along the active layers and connected to the thermoelectric conductors thereby allowing the thermoelectric conductors to expand and contract relative to one another thereby improving effectiveness and extending lifespan of the apparatus.

The thermoelectric conductors are aligned in a single row presenting a channel inside each of said thermoelectric conductors exchange heat with non-electro conductive fluid circulated therethrough wherein the channels are defined by a hollow construction of each wedge with each hollow configuration of each wedge being fluidly communicated with one another wherein non-electro conductive fluid directly engages inner surface of each of the inclined surfaces and the side surfaces of each of the wedges. The collectors for receiving and circulating non-electro conductive fluid are connected with each of the thermoelectric conductors and are removably connected with one another.

An advantage of the present invention is to provide an improved thermoelectric device or cluster including a plurality of thermoelectric conductors adjacent to one another with a plurality of active layers sandwiched between the thermoelectric conductors thereby allowing the thermoelectric conductors to expand and contract in various functional modes.

Another advantage of the present invention is to provide an improved thermoelectric device presenting a design of multiple thermoelectric conductors interconnected with one another unlike a unitary thermoelectric housing of prior art devices, thereby increasing efficiency of the inventive thermoelectric device by transferring the heat through the thermoelectric semiconductor avoiding any significant thermal barriers on the way of a heat flow to/from the active element sandwiched between the thermoelectric conductors.

Still another advantage of the present invention is to provide an improved thermoelectric device adaptable to keep robust operability despite the movements of its individual parts such as the thermoelectric conductors, caused by considerable temperature cyclic deformation.

Still another advantage of the present invention is to provide an improved thermoelectric device that guarantees a reliable protection to the active elements from an environmental impact and debris.

Other advantages and meritorious features of this invention will be more fully understood from the following description of the preferred embodiment, the appended claims, and the drawings; a brief description of which follows.

### BRIEF DESCRIPTION OF THE DRAWINGS

Other advantages of the present invention will be readily appreciated as the same becomes better understood by reference to the following detailed description when considered in connection with the accompanying drawings wherein:

FIG. 1 shows a partial cross sectional view of a thermoelectric device or a cluster of the present invention;

FIG. 1A illustrates a partial cross sectional view of one fragment of the thermoelectric cluster presenting at least two thermoelectric conductors presenting an active layer disposed or sandwiched between the thermoelectric conductors and surrounded by an elastic ring and a pair of connecting layers sandwiched between opposite surfaces of the active layer and the thermoelectric conductors;

FIG. 2 shows the general view of thermoelectric cluster;

FIG. 3 shows a coaxial design of a thermoelectric cluster;

FIG. 4 shows a cross sectional view of the thermoelectric cluster with six pairs of the active elements of a first embodiment of the present invention;

FIG. 5 shows another view of a thermoelectric set of the clusters taken from the angle of infrared heating;

FIG. 6 shows another view of the thermoelectric set of clusters as taken from the angle of a collector;

FIG. 7 shows a holding frame for the set of the clusters;

FIG. 8 shows flows of cooling non-electro conductive liquid in the set of clusters;

FIG. 9 shows a cross sectional view of a generator cluster of a second embodiment of the present invention;

FIG. 10 shows a side view of the set of the generator clusters of the second embodiment;

FIG. 11 shows a holding frame for a set of the clusters of the second embodiment;

FIG. 12 shows flows of heating non-electro conductive liquid in the set of the clusters;

FIG. 13 shows flows of cooling non-electro conductive liquid in the set of the clusters;

FIG. 14 shows a generator cluster of a third embodiment of the present invention;

FIG. 15 shows a side view of the set of the generator clusters in the third embodiment;

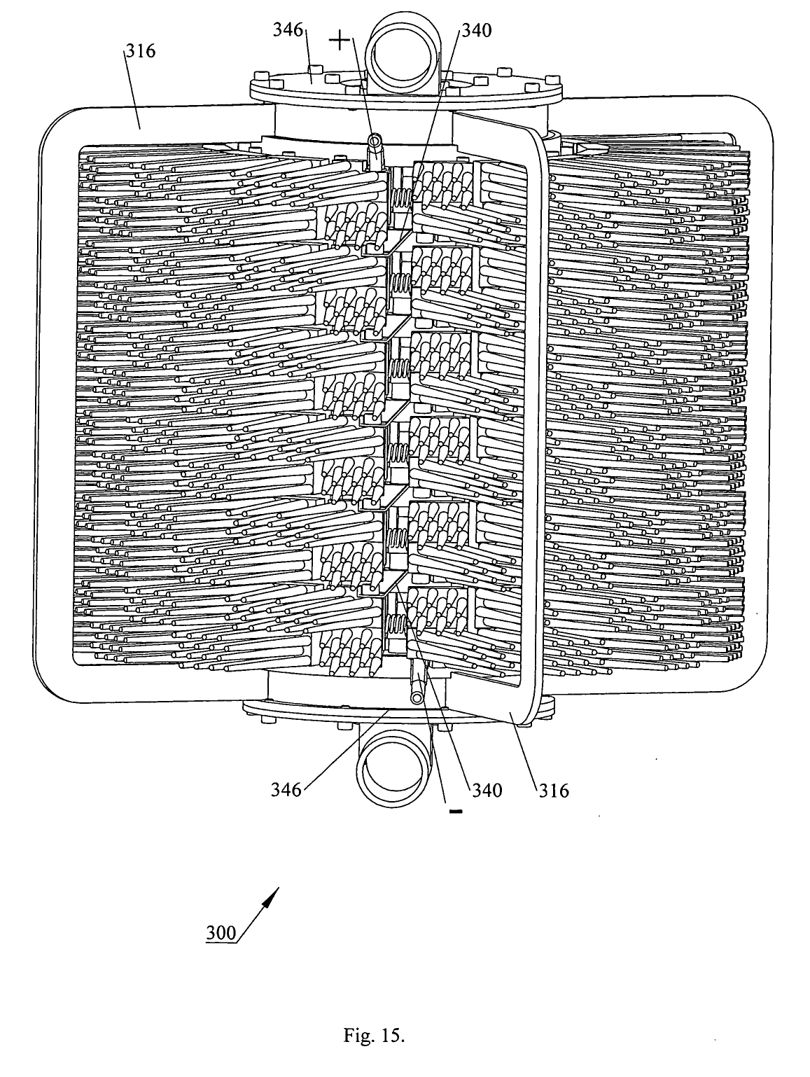

FIG. 16 shows a cross sectional view of the set of the generator clusters of the third embodiment;

FIG. 17 shows a top view of a generator cluster in a fourth embodiment;

FIG. 18 shows a side view of the set of the generator clusters of the fourth embodiment;

FIG. 19 shows a cross sectional view of the set of the generator clusters of the fourth embodiment;

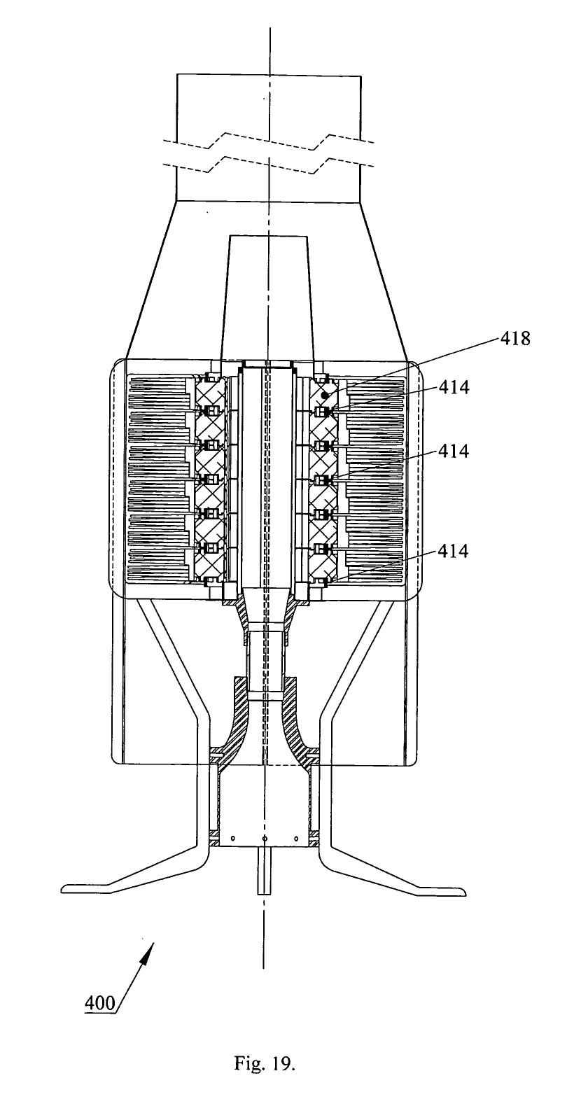

FIG. 20 shows a heat pump cluster of the first embodiment;

FIG. 21 shows a side view of the set of heat pump clusters of the first embodiment;

FIG. 22 shows a holding frame for a set of heat pump clusters of the first embodiment;

FIG. 23 shows streams of non-electro conductive liquid in a set of the clusters;

FIG. 24 shows streams of cooling non-electro conductive liquid in a set of the clusters;

FIG. 25 shows a heat pump cluster of the second embodiment;

FIG. 26 shows a side view of the set of heat pump clusters of the second embodiment; and

FIG. 27 shows a cross sectional view of the set of heat pump clusters of the second embodiment.

### DETAILED DESCRIPTION OF THE INVENTION

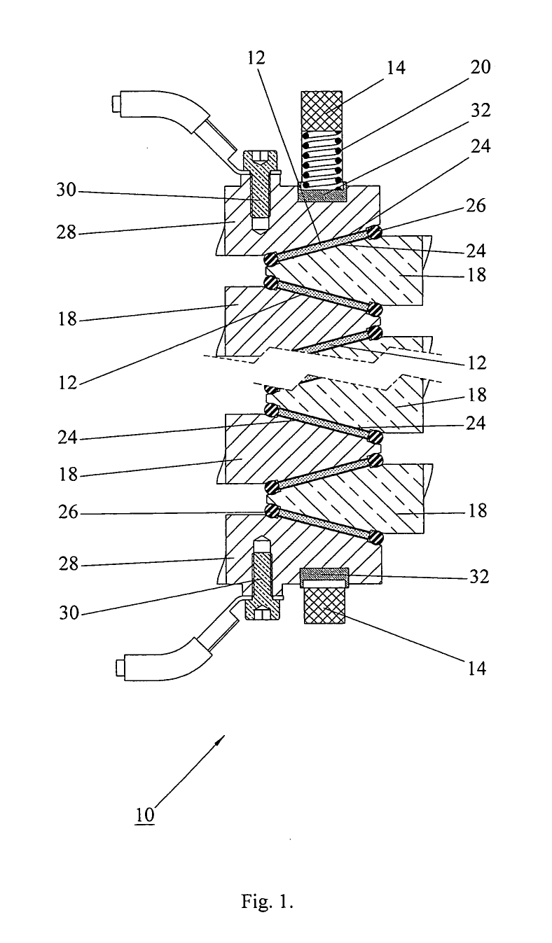

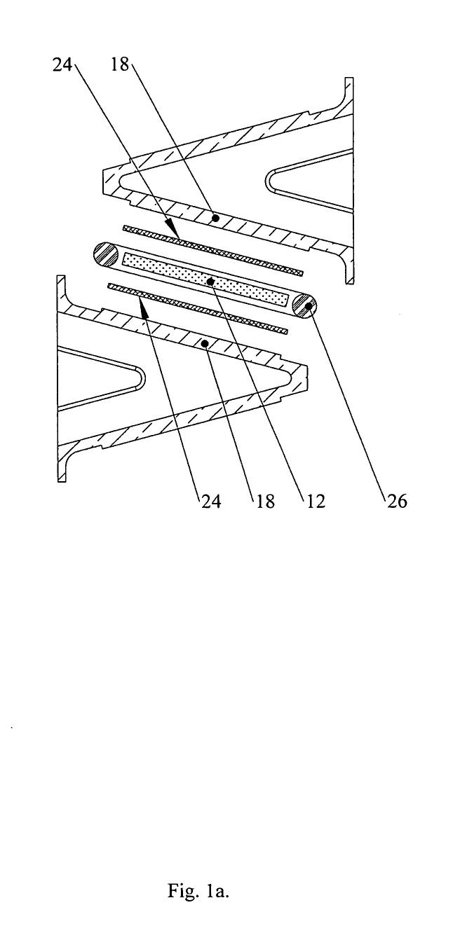

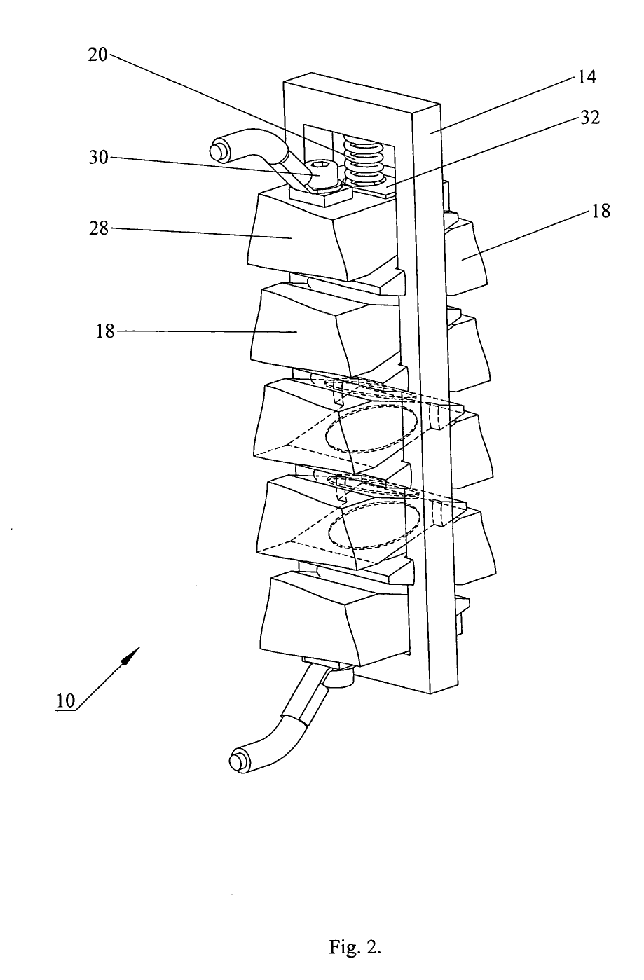

Referring to FIGS. 1 through 3, wherein like numerals indicate like or corresponding parts, an apparatus of the present invention is generally shown at 10. Based on various designs and intended industrial applications, the apparatus 10 of the present invention can perform various functions. The apparatus 10 can be utilized as a generator for converting thermal energy to electrical energy and a heat pump for transferring heat from a low temperature reservoir to a higher temperature reservoir. Numerous other industrial applications may employ the design of the present apparatus 10 without limiting the scope of the present invention.

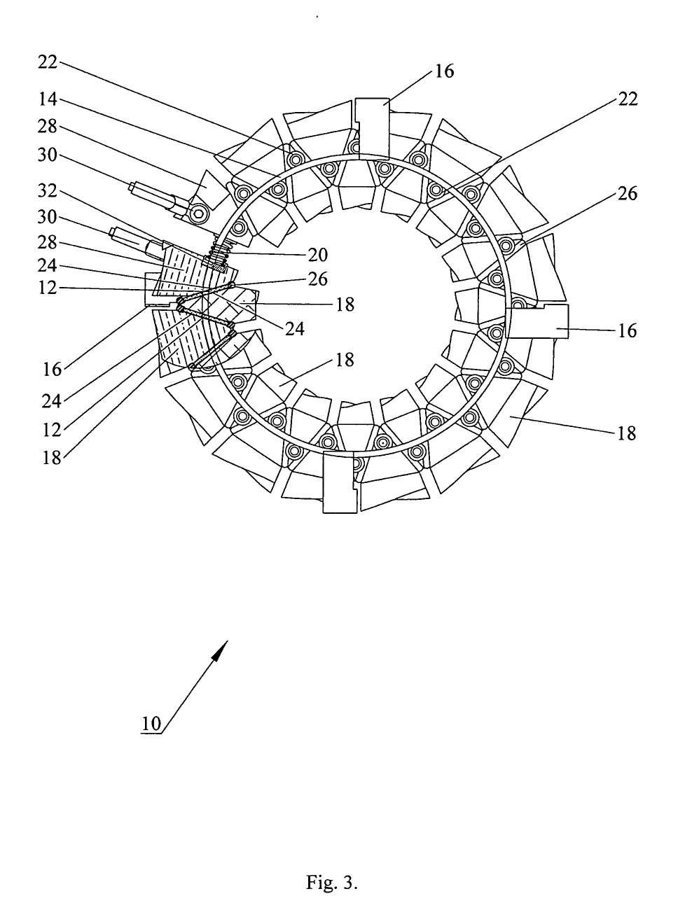

The apparatus 10 includes a cluster of a combination of a plurality of active elements or layers 12. The active layers 12 are fabricated in a shape of a washer and are positioned in the apparatus 10 in pairs of N- (negative) and P- (positive) types of conductivity thereby forming pairs or sets. The active layers 12 alternating between one another or between N- and P-type of conductivity, are elastically tightened along a plurality of guiding rails 14 extending from and mechanically engaged with a holding frame 16. The active layers 12 are sandwiched between thermoelectric conductors 18. The thermoelectric conductors 18 are forced against one another and connected with one another by an elastic element 20 such as spring. The shape of the guiding rails 14 of the holding frame 16 can also be defined in accordance with the specification, i.e. may be straight, curved up into a closed ring, as illustrated in FIG. 3, or spiral. Those skilled in mechanical art will appreciate that other resilient devices can be used in order to impact and hold the thermoelectric conductors 18 against one another. Other types and configurations of the frames 16 and rails 14 can be used as well. The particular design as illustrated in FIGS. 1 through 3 and disclosed herewith is not intended to limit the scope of the present invention. At the same time, the thermoelectric elements 18 are fixed from moving in other directions with the guiding rails 14 formed of non-electro conductive material or are electrically isolated from the thermoelectric conductors 18 by insulators 22. The peripheral thermoelectric conductors 28 presents a single contact surface and have a stop insulator 32 and also include the connection element 30 connected thereto and to the electric circuit.

The thermoelectric conductors 18 are also alternating in the fashion wherein some of the thermoelectric conductors 18 are positioned to receive heat by means of direct heat exchange with hot heat carrier and transfer heat to the active layers 12, and the other thermoelectric conductors 18 are configured to receive heat from the active layers 12 then pass it through and further by means of direct heat exchange with a cold heat carrier. The hot heat carrier can be presented by infrared radiation, vapor-gaseous medium, non-electro conductive fluid. The cold heat carrier can be presented by vapor-gaseous medium, non-electro conductive fluid. Another important aspect of the present invention, as best illustrated in FIG. 1A, are interconnecting layers 24 or thermoelectric sliding contacts. The interconnecting layer 24 is sandwiched between opposite surfaces of each active layer 12 and the thermoelectric conductors 18. The interconnecting layers 24 are formed from at least one of deformable substance of electro and thermo conductivity and a solder having a melting temperature point below operating temperature thereby improving effectiveness and extending lifespan of said apparatus 10 wherein the solder transforms between a deformable stage and a solid stage. The deformable substance is further defined by a soft paste-like material spreadable along the active layers 12 and connected to the thermoelectric conductors 18 thereby allowing the thermoelectric conductors 18 to expand and contract relative to one another. Other connecting method may be used with the present invention without limiting the scope of the present invention. The active layers 12 formed in a shape of a washer. The active layer 12 may present circular configuration and a non-circular configuration without limiting the scope of the present invention. The thickness may be even smaller as a thin film and may be less than 0.1 MM. The thickness will depend upon various thermo-environments as applied to the active layer 12. For example, the thinner is the thickness of the active layer 12 then less of expensive thermoelectric materials will be used in application and production of the active layer 12.

The active layers 12 are surrounded by a resilient element such as, for example, O-ring 26, to protect the active layers 12 and the sliding contact or interconnecting layer 24 from the external conditions, impacts, debris, fluids, etc. The positioning protective element, such the O-ring 26, is made in a shape of a silicone ring and placed in depressions or grooves defined in each thermoelectric conductor 18. The thermoelectric conductors 18 are formed from any type of thermo and electro conductive material having properties that are not affected by temperature of heat and electrical current going therethrough thereby providing the thermoelectric conductors 18 that are non destructible and able to function under all thermal conditions.

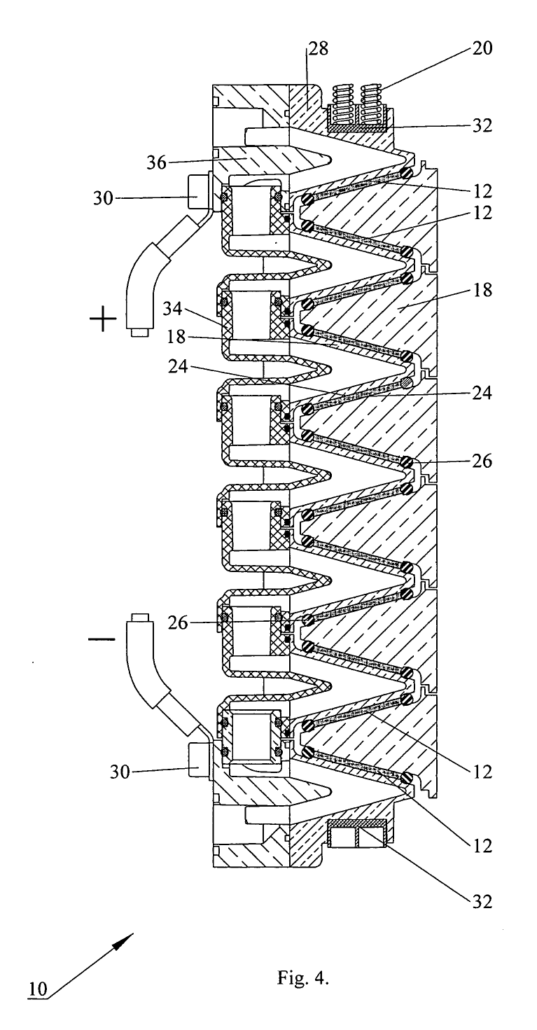

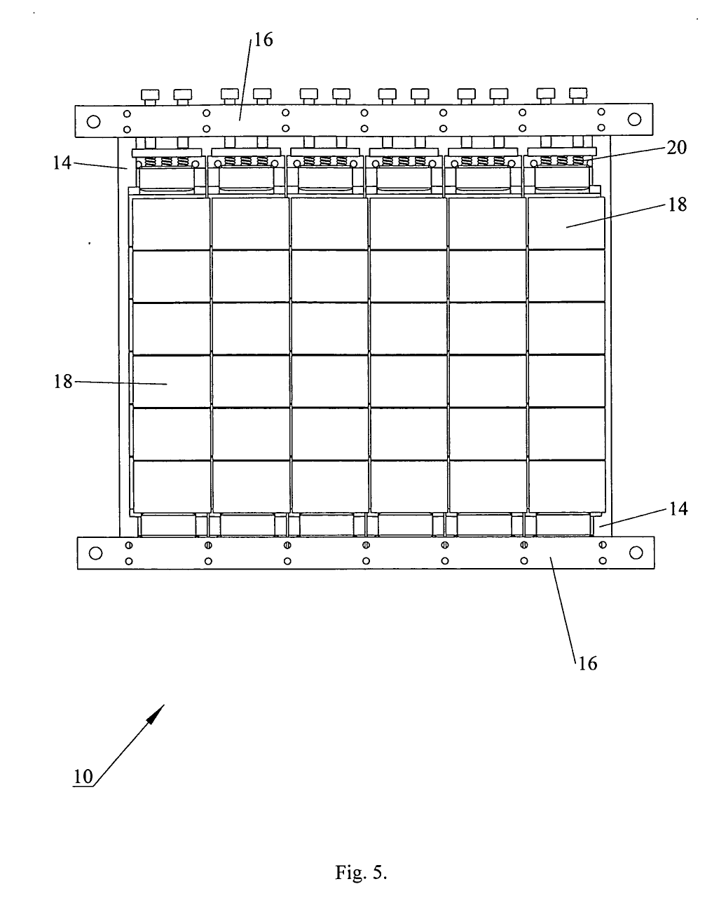

FIG. 4-8 shows generator of a first embodiment of the present invention. Referring to FIGS. 4 through 8, wherein like numerals indicate like or corresponding parts, an apparatus of the present invention is generally shown at 10. Based on various designs and intended industrial applications, the apparatus 10 of the present invention can perform various functions. Numerous other industrial applications may employ the design of the present apparatus 10 without limiting the scope of the present invention.

The apparatus 10 includes a cluster of a combination of a plurality of active elements or layers 12. The active layers 12 are fabricated in a shape of a washer and are positioned in the apparatus 10 in pairs of N- (negative) and P- (positive) types of conductivity thereby forming pairs or sets. The active layers 12 alternating between one another or between N- and P-type of conductivity, are elastically tightened along a plurality of guiding rails 14 extending from and mechanically engaged with a holding frame 16. The active layers 12 are sandwiched between thermoelectric conductors 18. The thermoelectric conductors 18 are forced against one another and connected with one another by an elastic element 20 such as spring. The shape of the guiding rails 14 of the holding frame 16 is straight. Other types and configurations of the frames 16 and rails 14 can be used as well. The particular design as illustrated in FIGS. 4 through 8 and disclosed herewith is not intended to limit the scope of the present invention. At the same time, the thermoelectric elements 18 are fixed from moving in other directions with the guiding rails 14 formed of stainless steel and are electrically isolated from the thermoelectric conductors 18 by insulators 22.

The thermoelectric conductors 18 are also alternating in the fashion wherein some of the thermoelectric conductors 18 are positioned to receive heat by means of direct heat exchange with hot heat carrier and transfer heat to the active layers 12, and the other thermoelectric conductors 18 are configured to receive heat from the active layers 12 then pass it through and further by means of direct heat exchange with cold heat carrier. In apparatus 10, the hot heat carrier is presented by infrared radiation. The cold heat carrier is presented by non-electro conductive liquid. Another important aspect of the present invention, as best illustrated in FIG. 1A, is an interconnecting layers 24 or thermoelectric sliding contacts. The interconnecting layer 24 is sandwiched between opposite surfaces of each active layer 12 and the thermoelectric conductors 18. The interconnecting layers 24 are formed from at least one of deformable substance of electro and thermo conductivity and a solder having a melting temperature point below operating temperature thereby improving effectiveness and extending lifespan of said apparatus 10 wherein the solder transforms between a deformable stage and a solid stage. The deformable substance is further defined by a soft paste-like material spreadable along the active layers 12 and connected to the thermoelectric conductors 18 thereby allowing the thermoelectric conductors 18 to expand and contract relative to one another. Other connecting method may be used with the present invention without limiting the scope of the present invention. The active layers 12 formed in a shape of a washer. The active layer 12 may present circular configuration and a non-circular configuration without limiting the scope of the present invention. The thickness may be even smaller as a thin film and may be less than 0.1 MM. The thickness will depend upon various thermo-environments as applied to the active layer 12. For example, the thinner is the thickness of the active layer 12 then less of expensive thermoelectric materials will be used in application and production of the active layer 12. The peripheral thermoelectric conductors 28 present a single contact surface and have a stop insulator 32.

The active layers 12 are surrounded by a resilient element such as, for example, O-ring 26, to protect the active layers 12 and the sliding contact or interconnecting layer 24 from the external conditions, impacts, debris, fluids, etc. The positioning protective element, such the O-ring 26, is made in a shape of a silicone ring and placed in depressions or grooves defined in each thermoelectric conductor 18.

Alluding to the above, the receiving thermoelectric conductors 18, positioned on one side of the apparatus 10, are made as a whole piece out of bronze by a method of casting with moldable models followed by machining the contact surfaces. All receiving thermoelectric conductors 18 have nielloed surface for receiving the infrared radiation. This design eliminates electrical contact between adjacent thermoelectric conductors 18 and provides a continuous closure of the infrared radiation reception area, as illustrated in FIG. 4. All so called giving thermoelectric conductors 18, positioned on the other side of the apparatus 10, are also made out of bronze by a method of casting with moldable models followed by machining the contact surfaces. At the same time, they are made hollow to allow the circulation of cooling non-electro conductive liquid. Every giving thermoelectric conductor 18 is supplemented with a segment of a collector 34, made out of a non-electro conductive material, to form a channel for a liquid flow. The segments of the collector 34 are removably interconnected with the apparatus 10. A pair of periphery or terminal segments of the collector 36 conduct electricity and include the connection element 30 connected thereto and to the electric circuit.

The thermoelectric conductors 18 are aligned in a single row presenting a channel inside each of the thermoelectric conductors 18 and are cooled by non-electro conductive fluid circulated therethrough. The channels are defined by a hollow configuration of each wedge with each hollow configuration of each of the wedges being fluidly communicated with one another wherein non-electro conductive fluid directly thermally engages inner surface of each the inclined surfaces and side surfaces of each of the wedges thereby improving effectiveness and extending lifespan of the apparatus 10. The collector 34 for receiving and circulating non-electro conductive fluid are connected with each of the thermoelectric conductors 18 and each of the collectors 34 are removably connected with one another. The thermoelectric conductors 18 are further defined by heat thermoelectric conductors and cold thermoelectric conductors wherein the cold thermoelectric conductors are alternated with the heat thermoelectric conductors thereby defining a cold side of the apparatus 10 and a heat side of the apparatus 10.

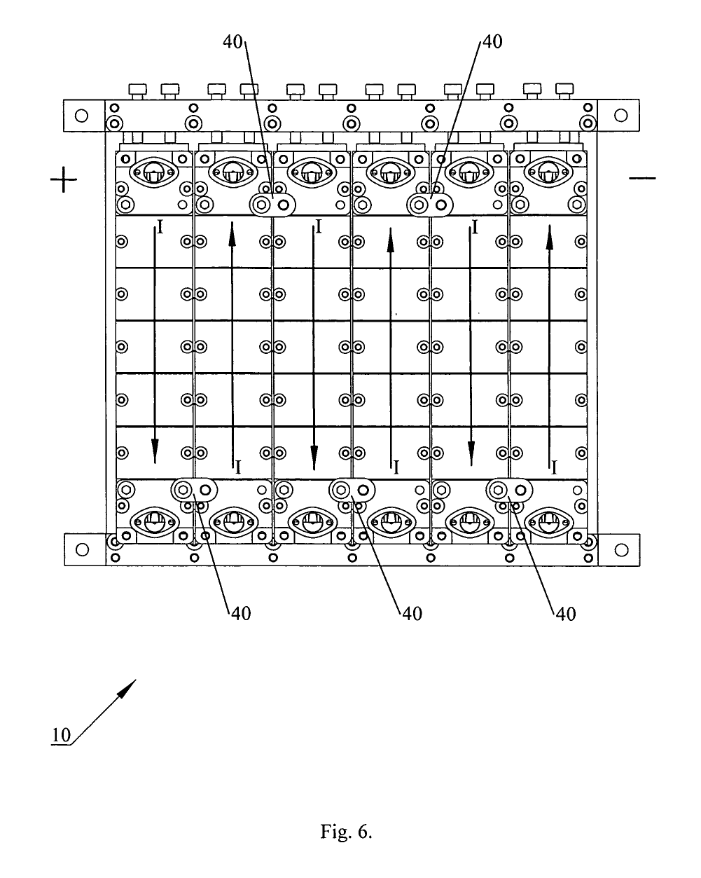

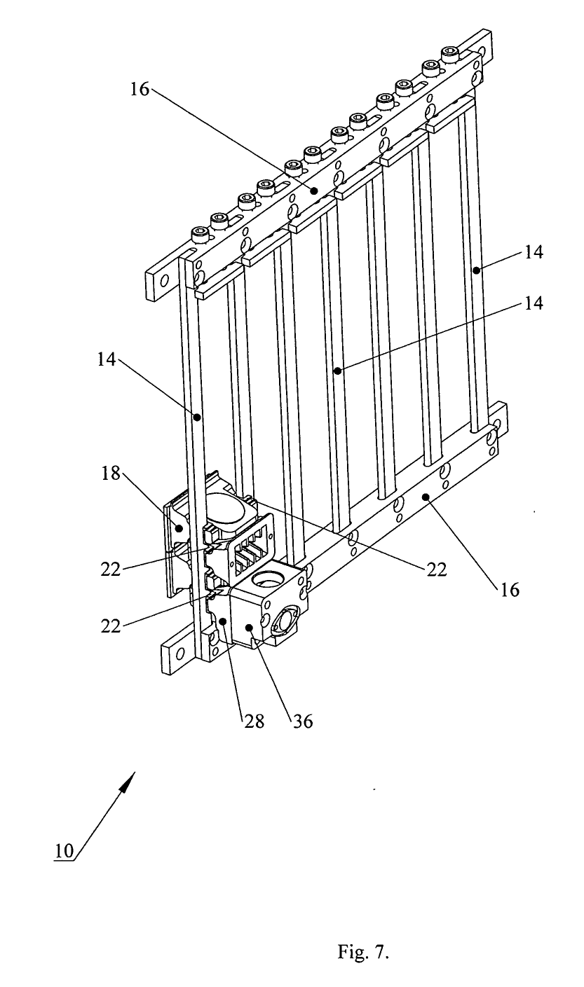

When assembled in groups, the thermoelectric conductors 18 and the active layers 12 are connected in the successive circuit by electricity conductive bridges 40 and are aligned in such a way that the direction of electric current in the adjacent group are mutually opposite, as illustrated in FIG. 6. The guiding rails 14 of all the groups are strait, made of stainless steel and integrated into the holding frame 16. Here, each thermoelectric conductor 18 is isolated from the guiding rails 14 by the ceramic insulator 22 as shown in FIG. 7.

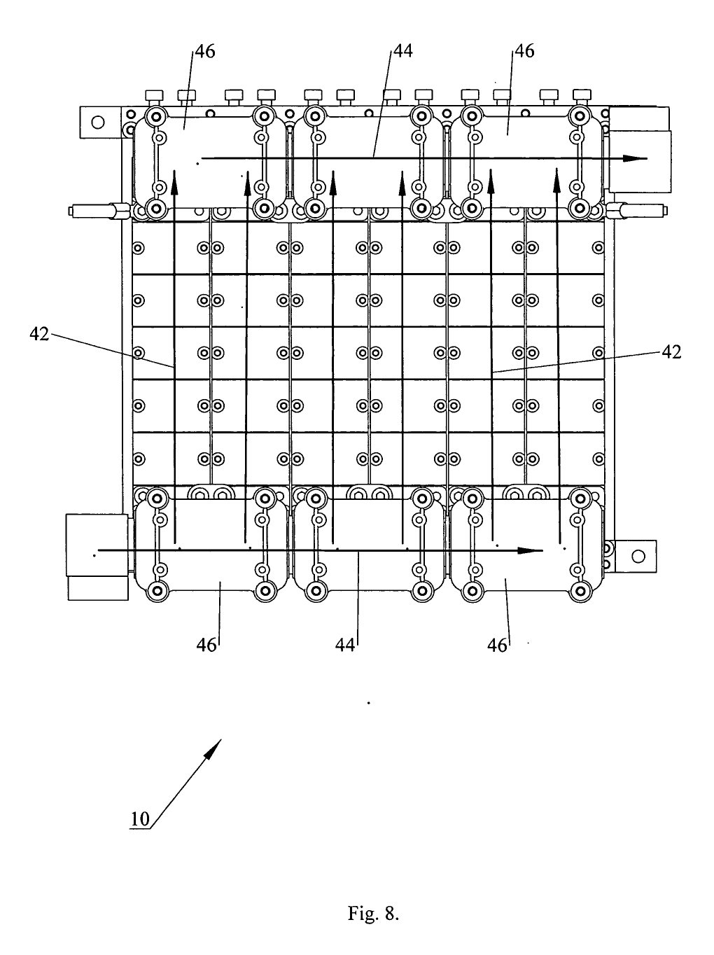

As illustrated in FIG. 8, arrows 42 show flows of cooling non-electro conductive liquid into the groups or clusters comprising the thermoelectric conductors 18 and the active layers 12. Arrows 44 show flows of cooling non-electro conductive liquid in the groups of collectors 46, flexibly interconnected in the groups by three. The non-electro conductive liquid that is heated by the giving thermoelectric conductors 18 is cooled down by discharging into the atmosphere through two radiators with forced blow by two fans (not illustrated). The circulation of fluid is executed by an electric pump. Additionally, the device has a case, an expansion tank, a plug load, an ammeter, a voltmeter, a heat indicator and an overload indicator.

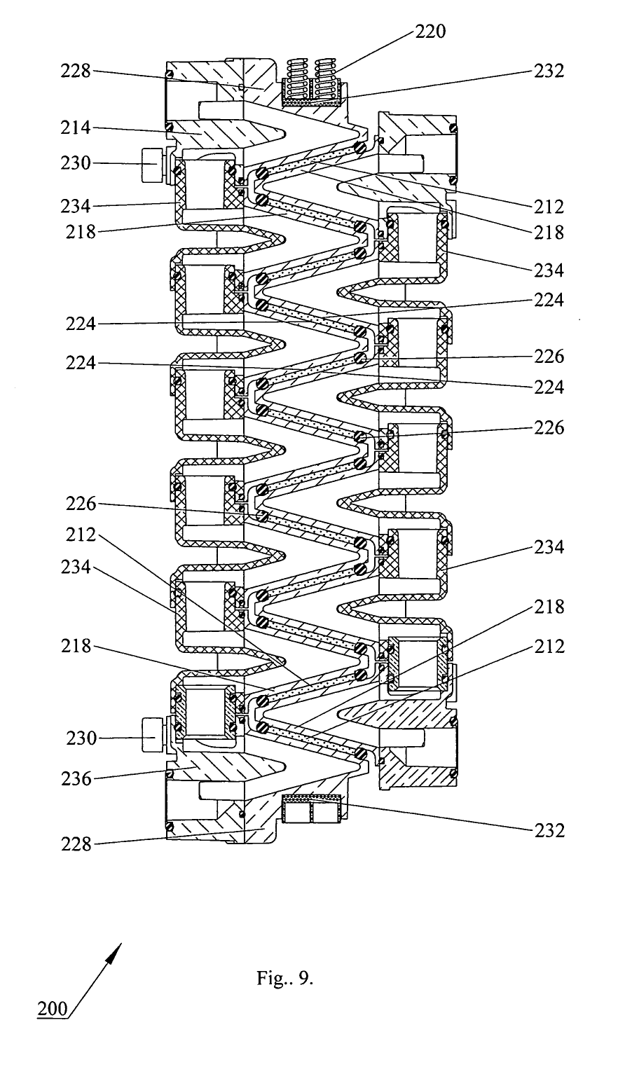

Referring no to FIG. 9, a generator of the second alternative embodiment is generally shown at 200. The generator 200 includes six clusters including six pairs of the thermoelectric conductors 218 and the active layers 212. The thermoelectric conductors 218 are alternating in the fashion wherein some of the thermoelectric conductors 18 are positioned to receive heat by means of direct heat exchange with a hot heat carrier and transfer heat to the active layers 12, and the other thermoelectric conductors 18 are configured to receive heat from the active layers 12 then pass it through and further by means of direct heat exchange with a cold heat carrier. In apparatus 200, the hot heat carrier is presented by non-electro conductive fluid. The cold heat carrier is presented by non-electro conductive fluid. Similar to the apparatus 10, the receiving thermoelectric conductors 218 are made out of bronze by a method of casting with moldable models followed by machining the contact surfaces. All receiving thermoelectric conductors 218 include a hollow body to allow the circulation of heating non-electro conductive liquid inside the conductors 218. Every receiving thermoelectric conductor 218 is supplemented with a segment of the collector 234, made out of a non-electro conductive material, to form a channel for a liquid flow. The segments of the collector 234 are flexibly interconnected in a set for the entire group of the thermoelectric conductors 218 and the active layers 212. Similarly, the giving thermoelectric conductors 218 are also made out of bronze by a method of casting with moldable models followed by machining the contact surfaces. At the same time, these thermoelectric conductors 218 present a hollow configuration in order to allow the circulation of cooling non-electro conductive liquid inside these thermoelectric conductors 218. The peripheral thermoelectric conductors 228 present a single contact surface and have a stop insulator 232. Every giving thermoelectric conductor 218 is supplemented with the segment of the collector 234, made out of a non-electro conductive material, to form a channel for a liquid flow. The segments of the collector 234 are flexibly interconnected in a set for the entire group of the thermoelectric conductors 218 and the active layers 212. Periphery segments of the collector 236 conduct electricity and possess the connection element 230 to the electric circuit.

The interconnecting layer 224 is sandwiched between opposite surfaces of each active layer 212 and the thermoelectric conductors 218, as best illustrated in FIG. 1A. The layers 224 are connected to the active layers 212 and the thermoelectric conductors 218. The interconnecting layers 224 are formed from at least one of deformable substance of electro and thermo conductivity and a solder having a melting temperature point below operating temperature thereby improving effectiveness and extending lifespan of the apparatus 200. The deformable substance is further defined by a soft paste-like material spreadable along the active layers 212 and connected to the thermoelectric conductors 218 thereby allowing the thermoelectric conductors 218 to expand and contract relative to one another. Other connecting method may be used with the present invention without limiting the scope of the present invention. The active layers 212 are formed in a shape of a washer have a diameter of 23 mm and a thickness of 1.55 mm. The thickness may be even smaller as a thin film and may be less than 0.1 mm. The thickness will depend upon various thermo-environments as applied to the active layer 212. For example, the thinner is the thickness of the active layer 212 then less of expensive thermoelectric materials will be used in application and production of the active layer 212. The active layers 212 are manufactured out of bismuth telluride obtained by powder metallurgical technique. To obtain the sliding contact 224 between the active layers 212 and the thermoelectric conductors 218, an alloy Rose with a melting point of 90 degrees Celsius is used. As the thermoelectric conductors 218 are flexibly pressed against the active layers 212, the elastic element 220, including six springs. Various other springs with different forces may be applied herewith without limiting the scope of the present invention and can be used based on rigidity of the thermoelectric materials.

The active layers 212 are surrounded by a resilient element such as, for example, O-ring 226, to protect the active layers 212 and the sliding contact or interconnecting layer 224 from the external conditions, impacts, debris, fluids, etc. The positioning protective element, such the O-ring 226, is made in a shape of a silicone ring and placed in depressions or grooves defined in each thermoelectric conductor 218.

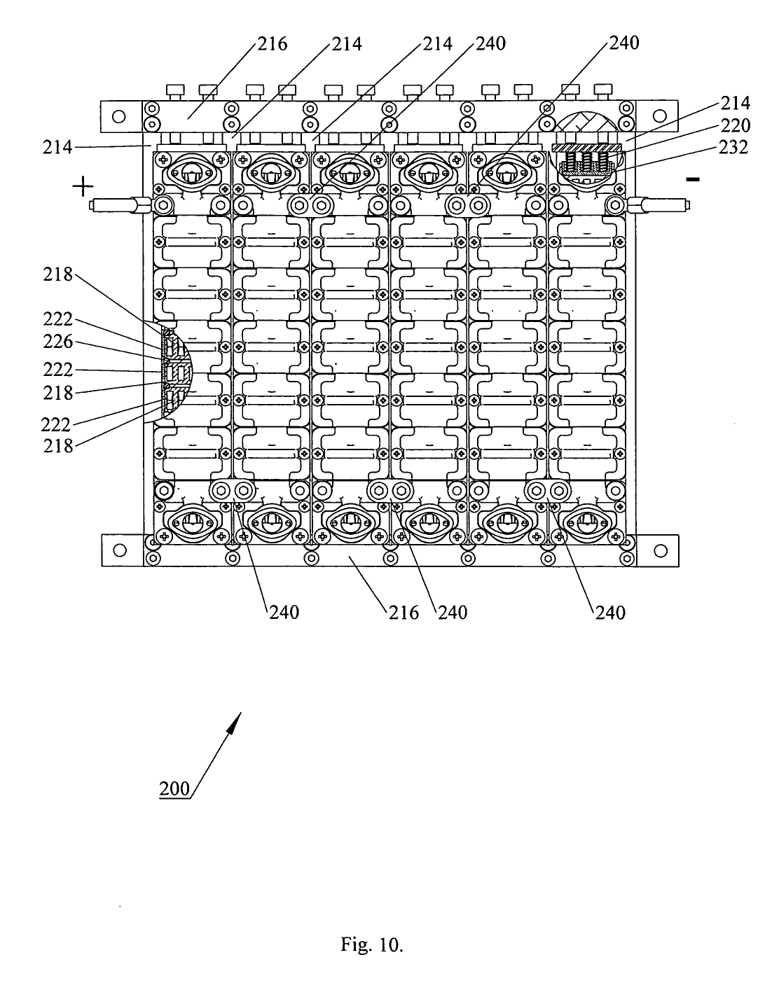

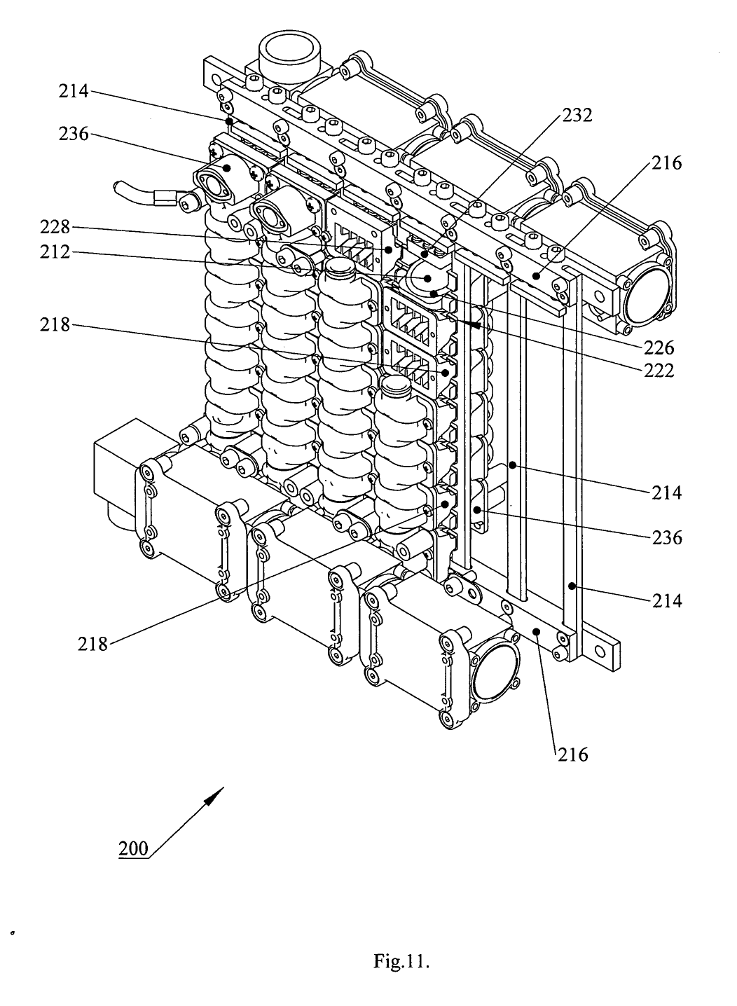

The hollow configuration of the receiving thermoelectric conductors 218 are conjugated with heated non-electro conductive fluid collectors 234 and the hollow configuration of the giving thermoelectric conductors 218 are conjugated with cold non-electro conductive collectors 234. The device consists of six groups or clusters positioned side by side to each other so that the hot side of all the clusters points in one direction and the cold side points in the opposite direction, as illustrated in FIGS. 10 and 11. When assembled in groups, the thermoelectric conductors 218 and the active layers 212 are connected in the successive circuit by electricity conductive bridges 240 and are aligned in such a way that the direction of electric current in the adjacent group are mutually opposite but other orientations may be used without limiting the scope of the present invention. The guiding rails 214 of all the groups are strait, made of stainless steel and integrated into the holding frame 216. Here, each thermoelectric conductor 218 is isolated from the guiding rails 214 by the ceramic insulator 222.

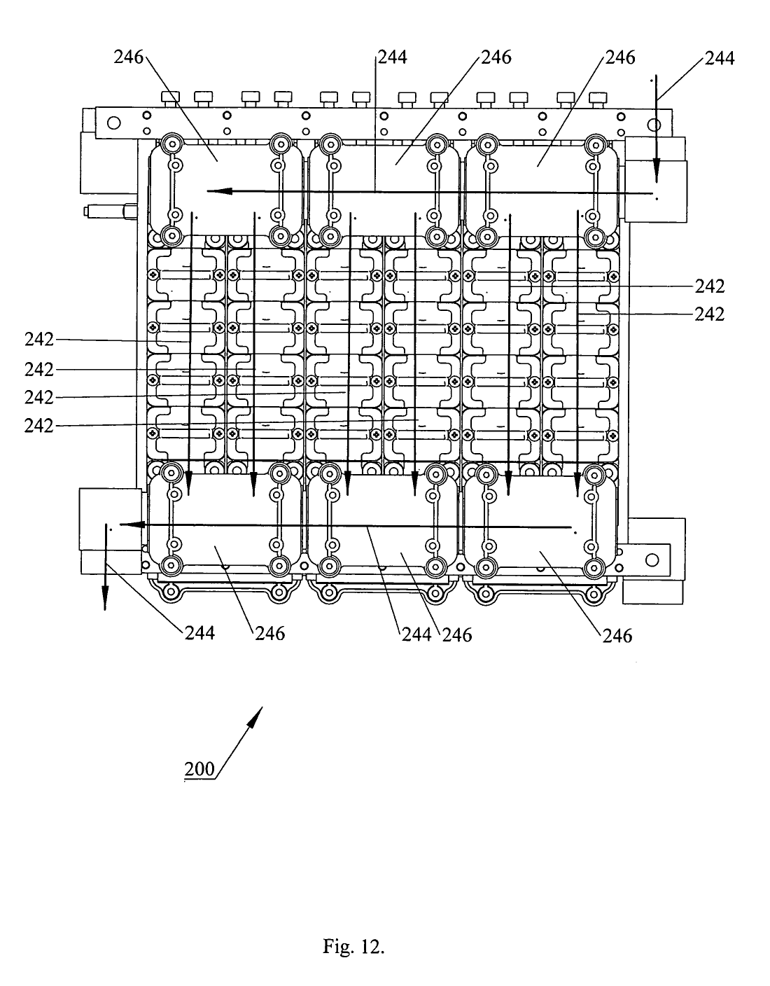

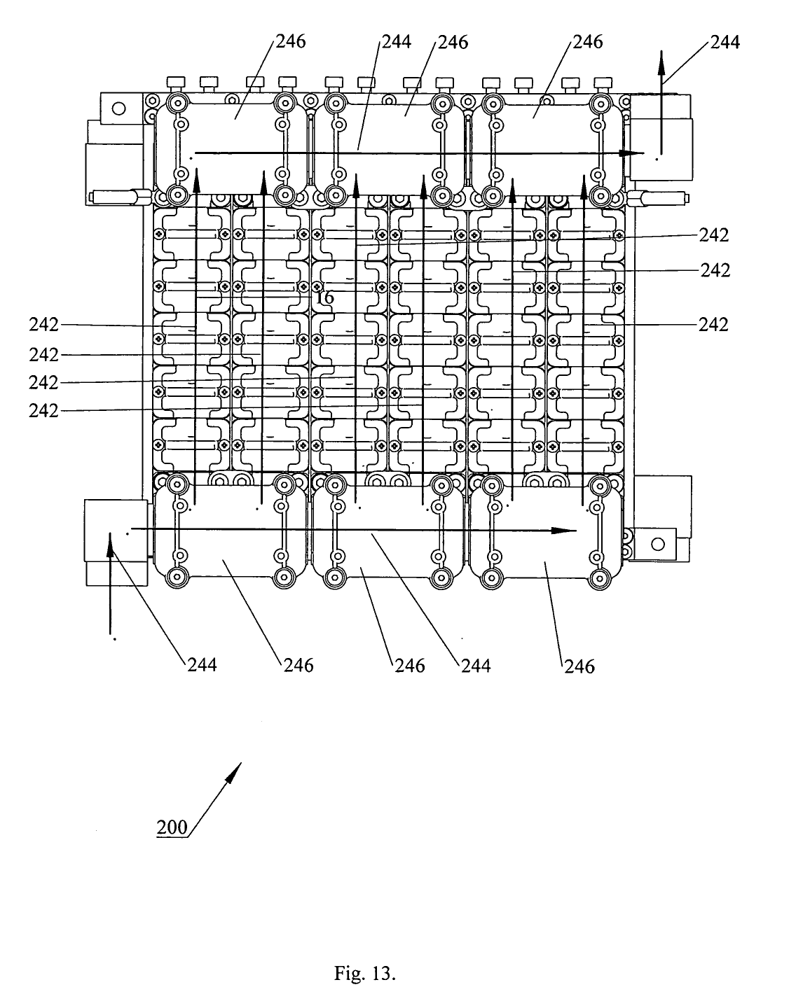

On FIG. 12, arrows 242 show the flow of heating non-electro conductive liquid in clusters. Arrows 244 show the flow of heating non-electro conductive liquid in the groups of uniting collectors 246, flexibly interconnected in the groups by three. On FIG. 13, arrow's 242 show the flow of cooling non-electro conductive liquid in the group or the clusters. Arrows 244 show the flow of cooling non-electro conductive liquid in the groups of uniting collectors 246, flexibly interconnected in the groups by three. The non-electro conductive liquid that is heated by the giving thermoelectric conductors is cooled down by discharging into the atmosphere through two radiators with forced blow by two fans. The circulation of cooling and heating fluids is executed by electric pumps. Additionally, the device has a case, an expansion tank, a plug load, an ammeter, a voltmeter, a heat indicator and an overload indicator. Those skilled in the art will appreciate that other components may be used without limiting the scope of the present invention. The components such as the aforementioned case, the expansion tank, the plug load, the ammeter, the voltmeter, the heat indicator and the overload indicator are used here with for exemplary purposes as one of the components to be used without any intent to limit the application of the present invention.

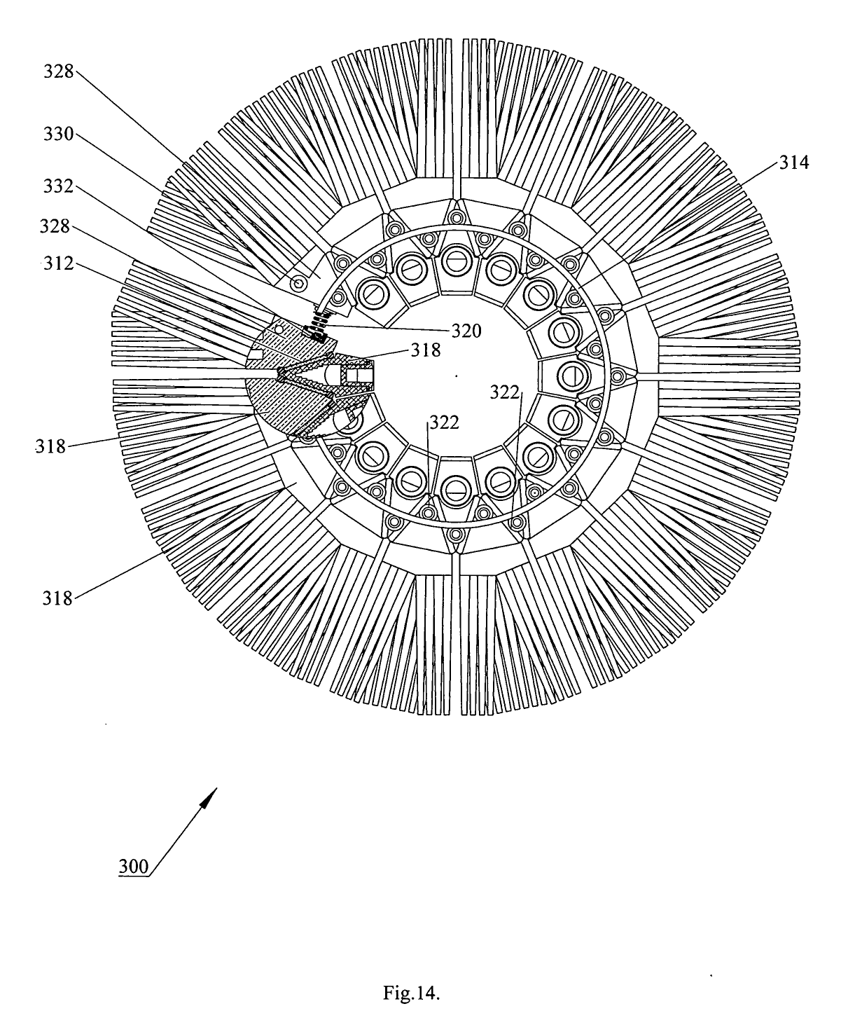

FIG. 14, 15, 16 shows a third alternative embodiment of the generator, generally shown at 300, is formed in to a circular closed ring. A third alternative embodiment of the generator includes at least one thermoelectric cluster that has thermoelectric conductors 318 heated up and cooled down by a liquid heat carriers and conductors that are respectively cooled down and heated up by a gas medium. Similar to the apparatus 10, the inner thermoelectric conductors 318 are made out of bronze by a method of casting with moldable models followed by machining the contact surfaces. All inner thermoelectric conductors 318 directly contacting with the fluid include a hollow body to allow the circulation of thermo exchanging non-electro conductive liquid inside the inner thermoelectric conductors 318. Every inner thermoelectric conductor 318 is supplemented with a segment of the collector 334, made out of a non-electro conductive material, to form a channel for a liquid flow. The material for the collector 334 must preserve the structural strength qualities while the heating liquid gets in contact with the collector. Ceramics, for example, can be used. The segments of the collector 334 are flexibly interconnected in a set for the entire group of the inner thermoelectric conductors 318 and the active layers 312. The outer thermoelectric conductors 318 are fabricated from aluminum alloys by a method of casting with moldable models followed by machining the contact surfaces. At the same time, these outer thermoelectric conductors 318 present shape of wedges that are in contact with the gaseous medium are finned for better interaction with the medium. Periphery thermoelectric conductors 328 include a terminal isolator 332 and possess the connection element 330 to the electric circuit.

The thermoelectric conductors 318 are also alternating in the fashion wherein some of the thermoelectric conductors 318 are positioned to receive heat and transfer heat to the active layers 312, and the other thermoelectric conductors 318 are configured to receive heat from the active layers 312 and then pass it through and further. The interconnecting layer 324 is formed from electro and thermo conductive material and formed from at least one deformable substance of electro and thermo conductivity and a solder having a melting temperature point below operating temperature thereby improving effectiveness and extending lifespan of the apparatus 300. The deformable substance is further defined by a soft paste-like material spreadable along the active layers 312 and connected to the thermoelectric conductors 318 thereby allowing the thermoelectric conductors 318 to expand and contract relative to one another. Other connecting method may be used with the present invention without limiting the scope of the present invention. The active layers 312 are formed in a shape of a washer have a diameter of 23 mm and a thickness of 1.55 mm. The active layers 312 are manufactured out of bismuth telluride obtained by powder metallurgical technique. To obtain the sliding contact 324 between the active layers 312 and the thermoelectric conductors 318, an alloy Rose with a melting point of 90 degrees Celsius is used. As the thermoelectric conductors 318 are flexibly pressed against the active layers 312, the elastic element 320, including six springs.

The active layers 312 are surrounded by a resilient element such as, for example, O-ring 326, to protect the active layers 312 and the sliding contact or interconnecting layer 324 from the external conditions, impacts, debris, fluids, etc. The positioning protective element, such the O-ring 326, is made in a shape of a silicone ring and placed in depressions or grooves defined in each thermoelectric conductor 318.

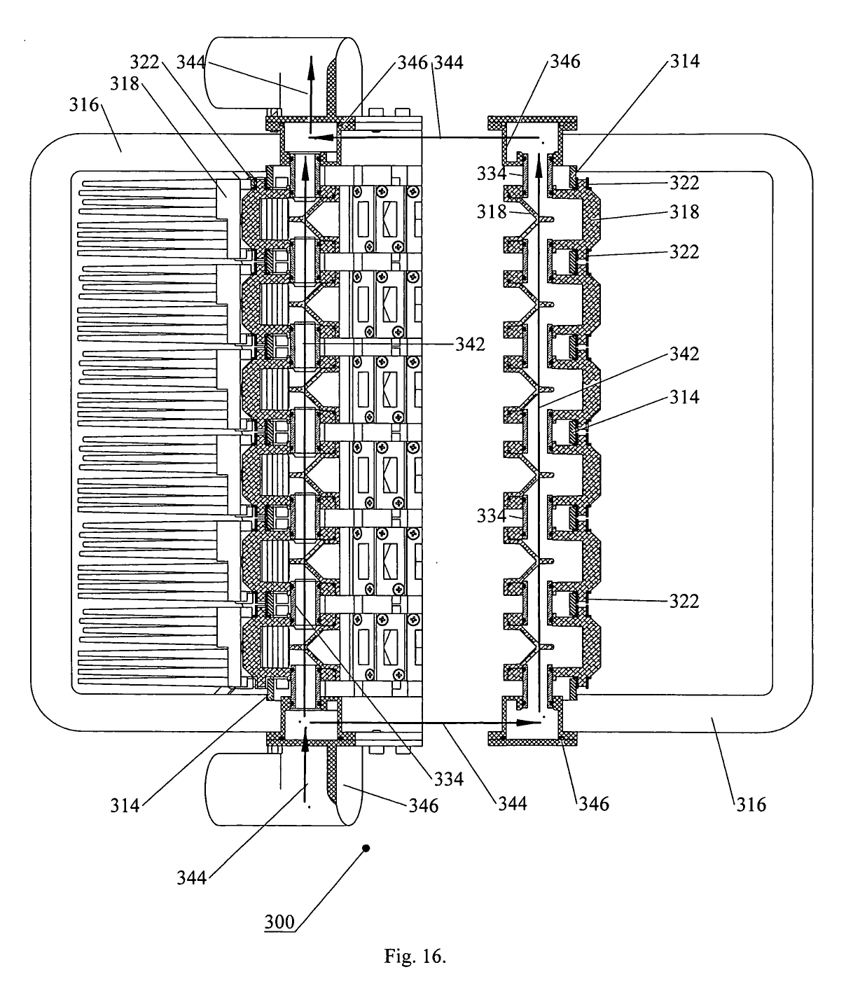

On FIG. 16, arrows 342 show the flow of non-electro conductive liquid in clusters. Arrows 344 show the flow of non-electro conductive liquid in the uniting collectors 346. The device is designed is such a way that the direction of a heat flow can be reversed without losing the functionality of the device, i.e. receiving and giving thermoelectric conductors can swap roles. In this case, the polarity of the generated voltage will reverse. Additionally, the device has a case, an expansion tank, a plug load, an ammeter, a voltmeter, a heat indicator and an overload indicator. Those skilled in the art will appreciate that other components may be used without limiting the scope of the present invention. The components such as the aforementioned case, the expansion tank, the plug load, the ammeter, the voltmeter, the heat indicator and the overload indicator are used here with for exemplary purposes as one of the components to be used without any intent to limit the application of the present invention.

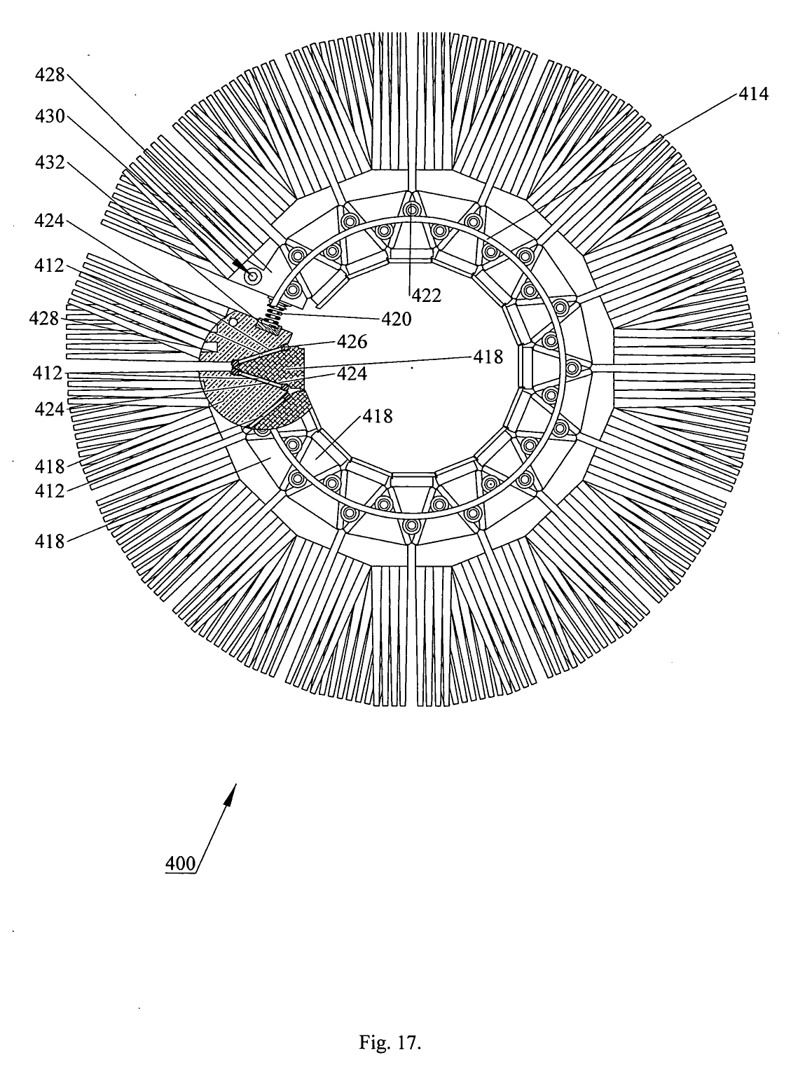

FIG. 17 illustrates a fourth embodiment, generally shown at 400. There are fifteen pair of active layers 412 mounted on two guiding rails 414 that have the shape of a circular closed ring. The thermoelectric conductors 418 are also alternating in the fashion wherein some of the thermoelectric conductors 418 are positioned to receive heat by means of direct heat exchange with a hot heat carrier and transfer heat to the active layers 412, and the other thermoelectric conductors 418 are configured to receive heat from the active layers 412 then pass it through and further by means of direct heat exchange with a cold heat carrier. The hot heat carrier is presented by infrared radiation. The cold heat carrier is presented by vapor-gaseous medium. The inner receiving thermoelectric conductors 418 are made out of bronze by a method of casting with moldable models followed by machining the contact surfaces. The outer giving thermoelectric conductors 418 are fabricated from aluminum alloys by a method of casting with moldable models followed by machining the contact surfaces. At the same time, these outer giving thermoelectric conductors 418 present shape of wedges that are in contact with the gaseous medium are finned for better interaction with the medium. Periphery thermoelectric conductors 428 include a terminal isolator 432 and possess the connection element 430 to the electric circuit.

The thermoelectric conductors 418 are flexibly pressed against the active layers 412 by the elastic element 420 including of one spring. The thermoelectric conductors 418 are also alternating in the fashion wherein some of the thermoelectric conductors 418 are positioned to receive heat and transfer heat to the active layers 412, and the other thermoelectric conductors 418 are configured to receive heat from the active layers 412 and then pass it through and further. The interconnecting layer 424 is formed from electro and thermo conductive material and formed from at least one of deformable substance of electro and thermo conductivity and a solder having a melting temperature point below operating temperature thereby improving effectiveness and extending lifespan of the apparatus 400. The deformable substance is further defined by a soft paste-like material spreadable along the active layers 412 and connected to the thermoelectric conductors 418 thereby allowing the thermoelectric conductors 418 to expand and contract relative to one another. Other connecting method may be used with the present invention without limiting the scope of the present invention. The active layers 412 are formed in a shape of a washer have a diameter of 23 mm and a thickness of 1.55 mm. The active layers 412 are manufactured out of bismuth telluride obtained by powder metallurgical technique. To obtain the sliding contact 424 between the active layers 412 and the thermoelectric conductors 418, an alloy Rose with a melting point of 90 degrees Celsius is used. As the thermoelectric conductors 418 are flexibly pressed against the active layers 412, the elastic element 420, such as spring.

The active layers 412 are surrounded by a resilient element such as, for example, O-ring 426, to protect the active layers 412 and the sliding contact or interconnecting layer 424 from the external conditions, impacts, debris, fluids, etc. The positioning protective element, such the O-ring 426, is made in a shape of a silicone ring and placed in depressions or grooves defined in each thermoelectric conductor 418.

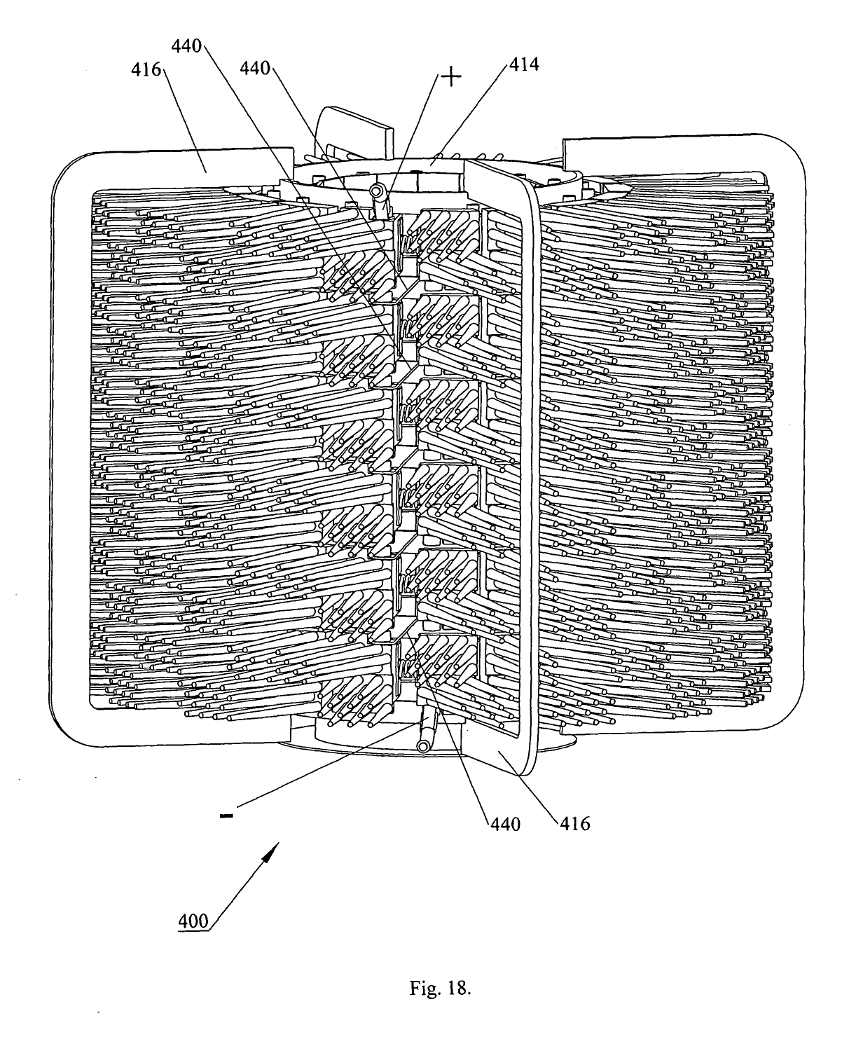

The device consists of six identical clusters positioned one above the other forming a single cylindrical surface for reception of infrared radiation inside themselves, as shown in FIG. 18. When assembled in groups, the thermoelectric conductors 418 and the active layers 412 are connected in the successive circuit by electricity conductive bridges 440. The source of the infrared radiation is an infrared finger burner. The axis of the burner coincides with the one of all the Clusters.

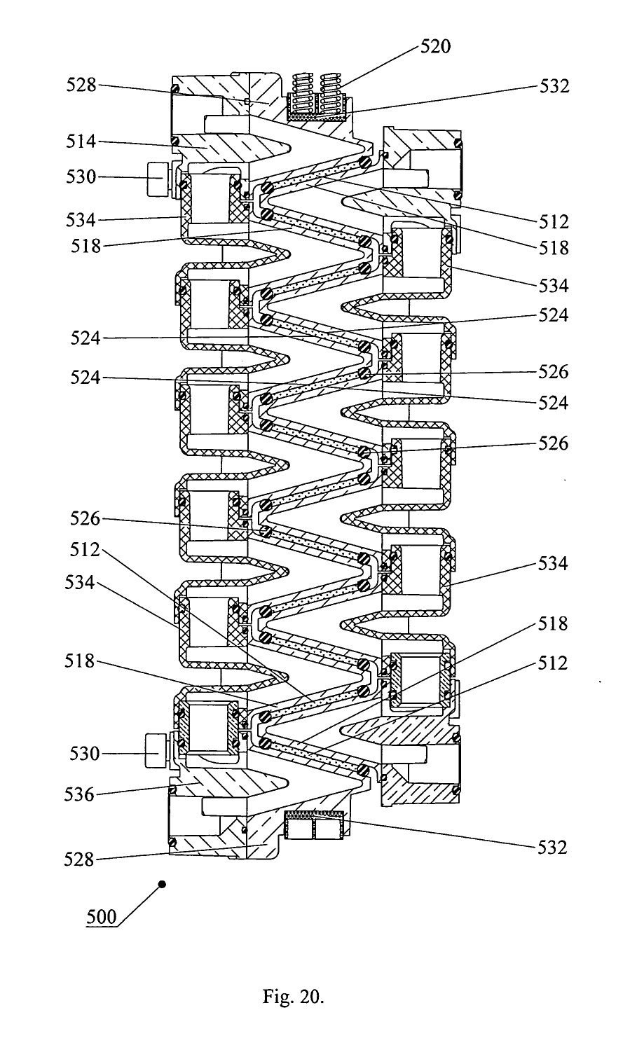

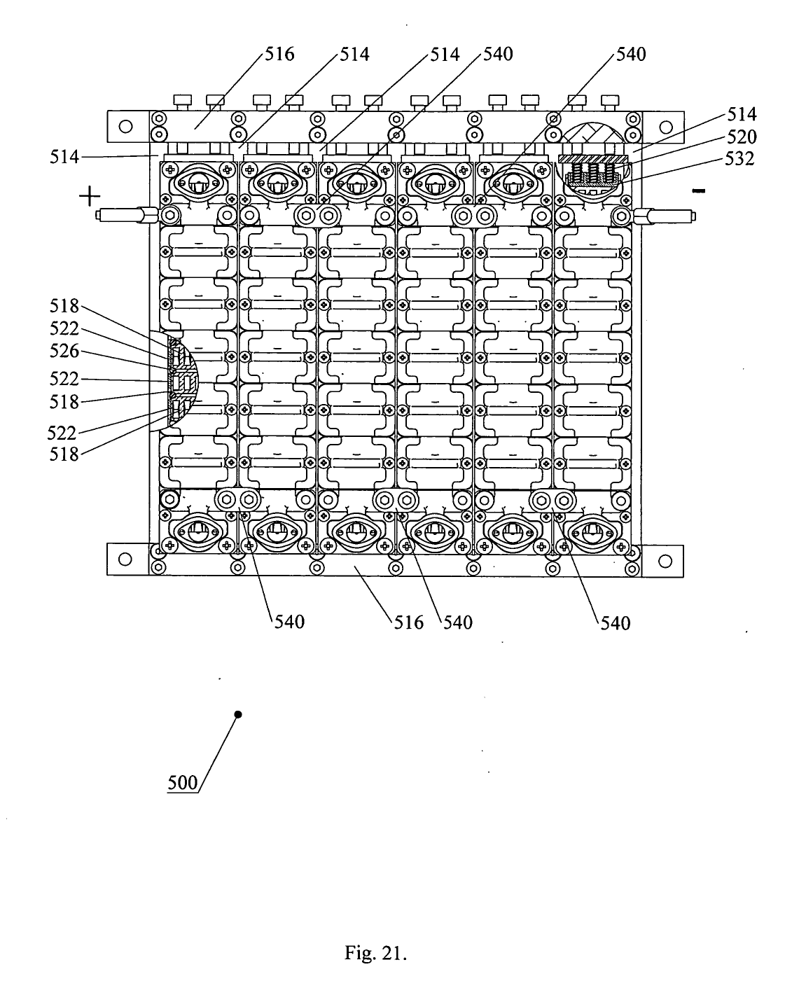

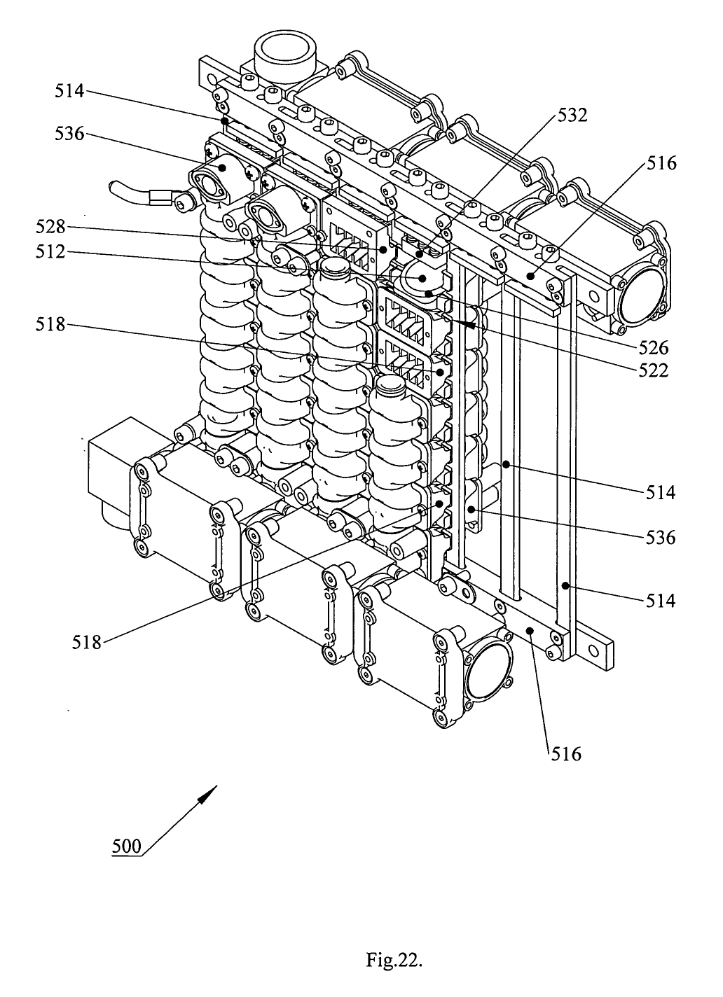

Referring no to FIGS. 20-24, a heat pump of a first embodiment is generally shown at 500. The heat pump 500 includes six clusters including six pairs of the thermoelectric conductors 518 and the active layers 512. The thermoelectric conductors 518 are alternating in the fashion wherein some of the thermoelectric conductors 518 are positioned to receive heat by means of direct heat exchange with a hot heat carrier and transfer heat to the active layers 512, and the other thermoelectric conductors 518 are configured to receive heat from the active layers 512 then pass it through and further by means of direct heat exchange with a cold heat carrier. In apparatus 500, the hot heat carrier is presented by non-electro conductive fluid. The cold heat carrier is presented by non-electro conductive fluid. Similar to the apparatus 10, the receiving thermoelectric conductors 518 are made out of bronze by a method of casting with moldable models followed by machining the contact surfaces. All receiving thermoelectric conductors 518 include a hollow body to allow the circulation of heating non-electro conductive liquid inside the conductors 518. Every receiving thermoelectric conductor 518 is supplemented with a segment of the collector 534, made out of a non-electro conductive material, to form a channel for a liquid flow. The segments of the collector 534 are flexibly interconnected in a set for the entire group of the thermoelectric conductors 518 and the active layers 512. Similarly, the giving thermoelectric conductors 518 are also made out of bronze by a method of casting with moldable models followed by machining the contact surfaces. At the same time, these thermoelectric conductors 518 present a hollow configuration in order to allow the circulation of cooling non-electro conductive liquid inside these thermoelectric conductors 518. The peripheral thermoelectric conductors 528 present a single contact surface and have a stop insulator 532.

Every giving thermoelectric conductor 518 is supplemented with the segment of the collector 534, made out of a non-electro conductive material, to form a channel for a liquid flow. The segments of the collector 534 are flexibly interconnected in a set for the entire group of the thermoelectric conductors 518 and the active layers 512. Periphery segments of the collector 536 conduct electricity and possess the connection element 530 to the electric circuit.

The interconnecting layer 524 is sandwiched between opposite surfaces of each active layer 512 and the thermoelectric conductors 518, as best illustrated in FIG. 1A. The layers 524 are connected to the active layers 512 and the thermoelectric conductors 518. The interconnecting layers 524 are formed from at least one of deformable substance of electro and thermo conductivity and a solder having a melting temperature point below operating temperature thereby improving effectiveness and extending lifespan of the apparatus 500. The deformable substance is further defined by a soft paste-like material spreadable along the active layers 512 and connected to the thermoelectric conductors 518 thereby allowing the thermoelectric conductors 518 to expand and contract relative to one another. Other connecting method may be used with the present invention without limiting the scope of the present invention. The active layers 512 are formed in a shape of a washer have a diameter of 23 mm and a thickness of 1.55 mm. The thickness may be even smaller as a thin film and may be less than 0.1 mm. The thickness will depend upon various thermo-environments as applied to the active layer 512. For example, the thinner is the thickness of the active layer 512 then less of expensive thermoelectric materials will be used in application and production of the active layer 512. The active layers 512 are manufactured out of bismuth telluride obtained by powder metallurgical technique. To produce the sliding contact 524 between the active layers 512 and the thermoelectric conductors 518 electricity conductive paste UVS (Universal High electroconductive lubricant) “Superkont” produced by OOO “Bers”, Ekaterinburg is used (http://www.smazelektro.ru/supercont.html). As the thermoelectric conductors 518 are flexibly pressed against the active layers 512, the elastic element 520 such as spring. Various other springs with different forces may be applied herewith without limiting the scope of the present invention and can be used based on rigidity of the thermoelectric materials.

The active layers 512 are surrounded by a resilient element such as, for example, O-ring 526, to protect the active layers 512 and the sliding contact or interconnecting layer 524 from the external conditions, impacts, debris, fluids, etc. The positioning protective element, such the O-ring 526, is made in a shape of a silicone ring and placed in depressions or grooves defined in each thermoelectric conductor 518.

The hollow configuration of the receiving thermoelectric conductors 518 are conjugated with heated non-electro conductive fluid collectors 534 and the hollow configuration of the giving thermoelectric conductors 518 are conjugated with cold non-electro conductive collectors 534. The device consists of six groups or clusters positioned side by side to each other so that the hot side of all the clusters points in one direction and the cold side points in the opposite direction, as illustrated in FIGS. 20-24. When assembled in groups, the thermoelectric conductors 518 and the active layers 512 are connected in the successive circuit by electricity conductive bridges 540 and are aligned in such a way that the direction of electric current in the adjacent group are mutually opposite but other orientations may be used without limiting the scope of the present invention. The guiding rails 514 of all the groups are strait, made of stainless steel and integrated into the holding frame 516. Here, each thermoelectric conductor 518 is isolated from the guiding rails 514 by the ceramic insulator 522.

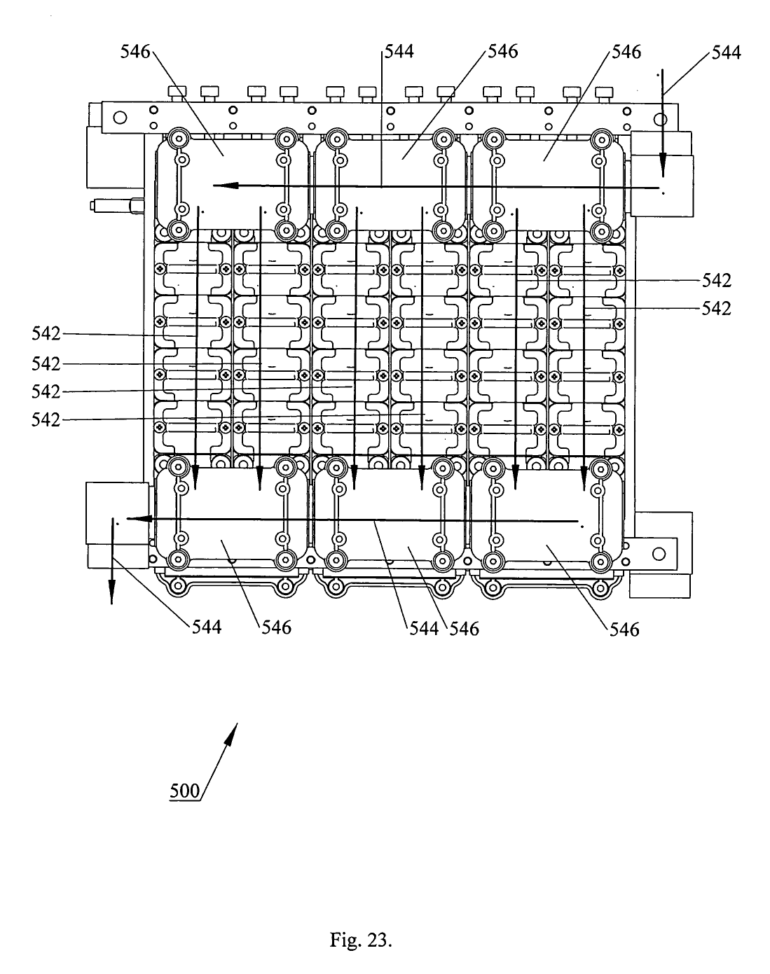

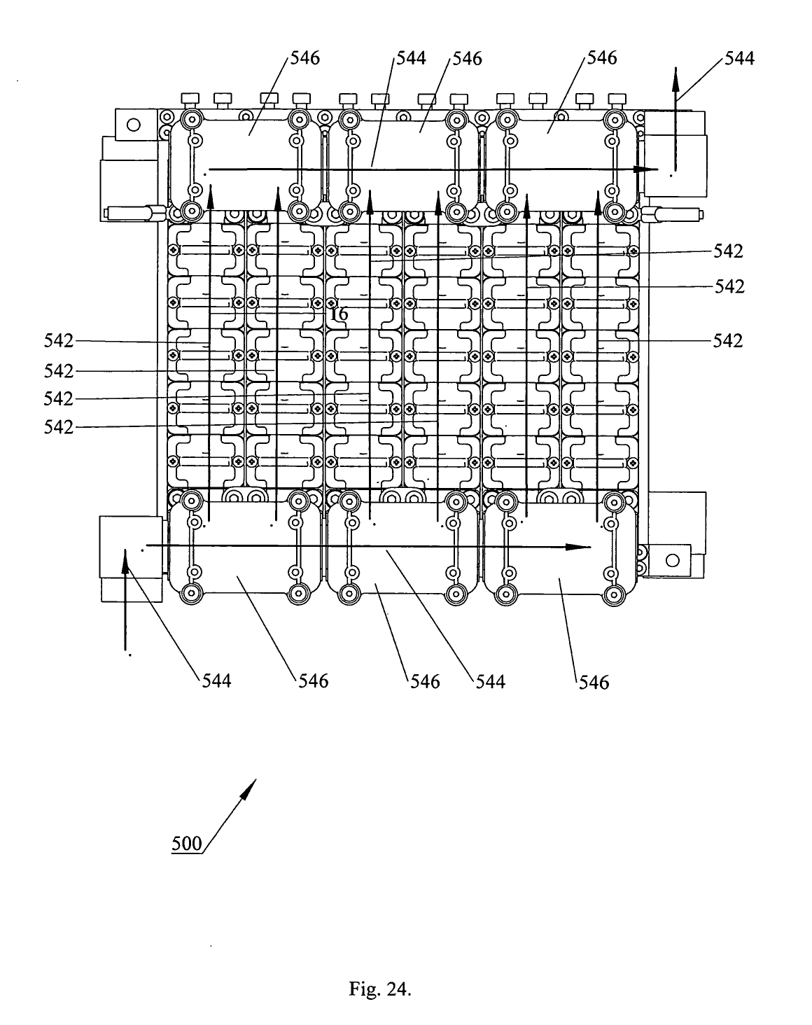

On FIG. 23, arrows 542 show the flow of heating non-electro conductive liquid in Clusters. Arrows 544 show the flow of heating non-electro conductive liquid in the groups of uniting collectors 546, flexibly interconnected in the groups by three. On FIG. 24, arrows 542 show the flow of cooling non-electro conductive liquid in the group or the clusters. Arrows 544 show the flow of cooling non-electro conductive liquid in the groups of uniting collectors 546, flexibly interconnected in the groups by three.

Cooling of the heated non-electro conductive liquid is done by releasing heat into the atmosphere through two radiators with forced blow by two fans. Heating of the cooled non-electro conductive liquid is done by taking away the heat from the closed space through a heat exchanger. Thus, there is a targeted cooling of a closed space. If necessary, the polarity of the electrical terminals can be reversed in order to heat this closed space. The circulation of both liquids is executed by an electric pump. Additionally, the device has a case, expansion tanks, and an operation control system of the heat pump. The device can stabilize the temperature in a closed thermo-insulated space where the installed equipment emits heat at a variable rate whereas the temperature outside varies as well. The components such as the aforementioned case, the expansion tanks, an operation control system of the heat pump are used here with for exemplary purposes as one of the components to be used without any intent to limit the application of the present invention.

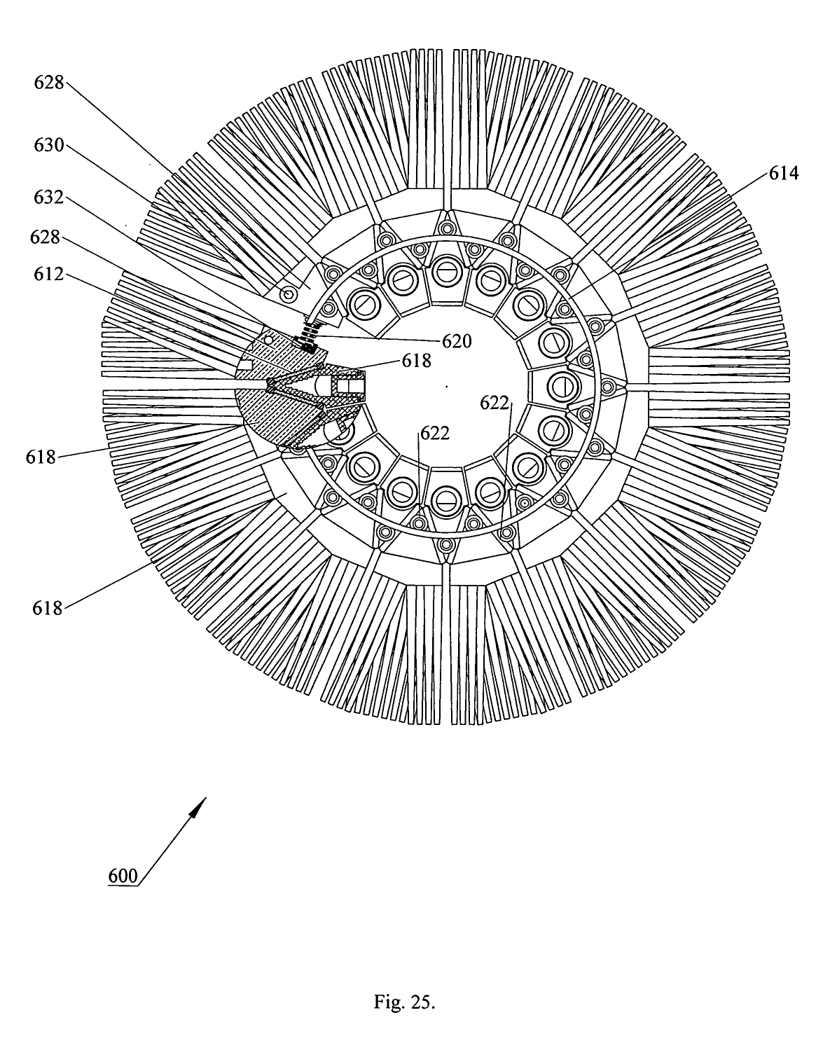

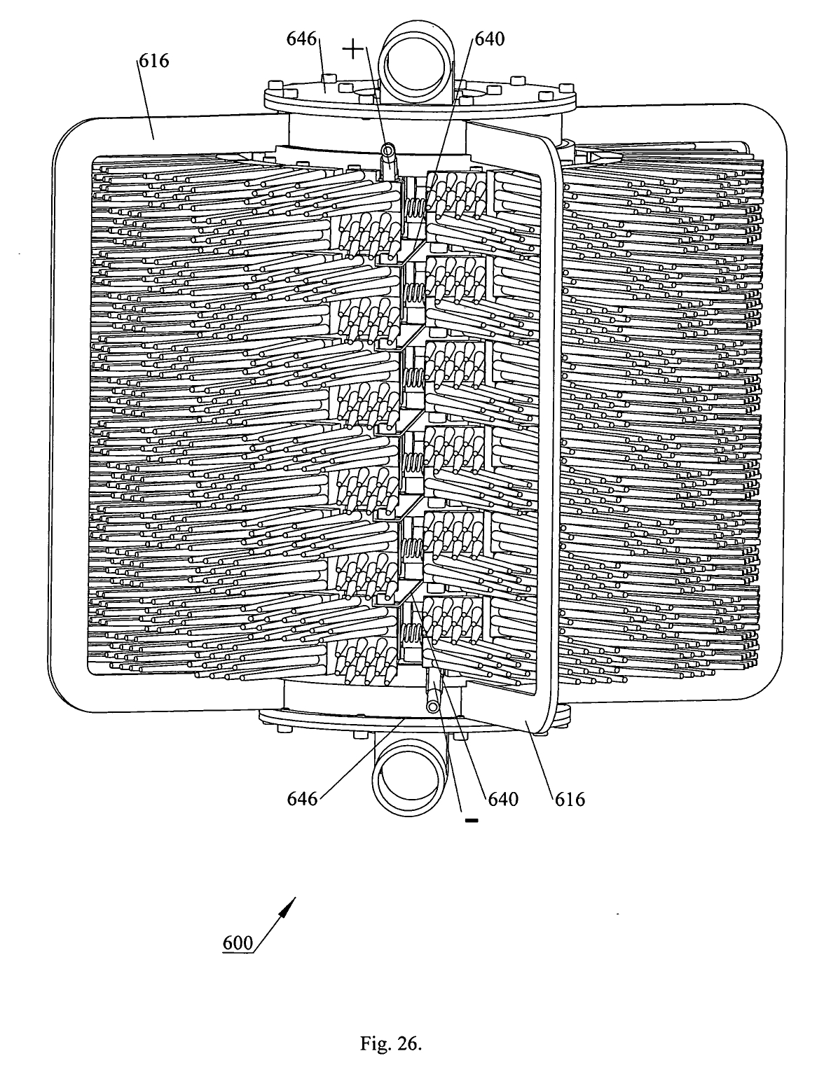

FIGS. 25-27 show a second alternative embodiment of the heat pump, generally shown at 600, is formed in to a circular closed ring. A second alternative embodiment of the heat pump includes at least one thermoelectric cluster that has thermoelectric conductors 618 heated up and cooled down by a liquid heat carriers and conductors that are respectively cooled down and heated up by a gas medium. Similar to the apparatus 10, the inner thermoelectric conductors 618 are made out of bronze by a method of casting with moldable models followed by machining the contact surfaces. All inner thermoelectric conductors 618 directly contacting with the fluid include a hollow body to allow the circulation of thermo exchanging non-electro conductive liquid inside the inner thermoelectric conductors 618. Every inner thermoelectric conductor 618 is supplemented with a segment of the collector 634, made out of a non-electro conductive material, to form a channel for a liquid flow. The material for the collector 634 must preserve the structural strength qualities while the heating liquid gets in contact with the collector. Ceramics, for example, can be used. The segments of the collector 634 are flexibly interconnected in a set for the entire group of the inner thermoelectric conductors 618 and the active layers 612. The outer thermoelectric conductors 618 are fabricated from aluminum alloys by a method of casting with moldable models followed by machining the contact surfaces. At the same time, these outer thermoelectric conductors 618 present shape of wedges that are in contact with the gaseous medium are finned for better interaction with the medium. Periphery thermoelectric conductors 628 include a terminal isolator 632 and possess the connection element 630 to the electric circuit.

The thermoelectric conductors 618 are also alternating in the fashion wherein some of the thermoelectric conductors 618 are positioned to receive heat and transfer heat to the active layers 612, and the other thermoelectric conductors 618 are configured to receive heat from the active layers 612 and then pass it through and further. The interconnecting layer 624 is formed from electro and thermo conductive material and formed from at least one deformable substance of electro and thermo conductivity and a solder having a melting temperature point below operating temperature thereby improving effectiveness and extending lifespan of the apparatus 600. The deformable substance is further defined by a soft paste-like material spreadable along the active layers 612 and connected to the thermoelectric conductors 618 thereby allowing the thermoelectric conductors 618 to expand and contract relative to one another. Other connecting method may be used with the present invention without limiting the scope of the present invention. The active layers 612 are formed in a shape of a washer have a diameter of 23 mm and a thickness of 1.55 mm. The active layers 612 are manufactured out of bismuth telluride obtained by powder metallurgical technique. To produce the sliding contact 624 between the active layers 612 and the thermoelectric conductors 618 electricity conductive paste UVS (Universal High electroconductive lubricant) “Superkont” produced by OOO “Berl”, Ekaterinburg is used (http://www.smazelektro.ru/supercont.html). As the thermoelectric conductors 618 are flexibly pressed against the active layers 612, the elastic element 620 such as spring.

The active layers 612 are surrounded by a resilient element such as, for example, O-ring 626, to protect the active layers 612 and the sliding contact or interconnecting layer 624 from the external conditions, impacts, debris, fluids, etc. The positioning protective element, such the O-ring 626, is made in a shape of a silicone ring and placed in depressions or grooves defined in each thermoelectric conductor 618.

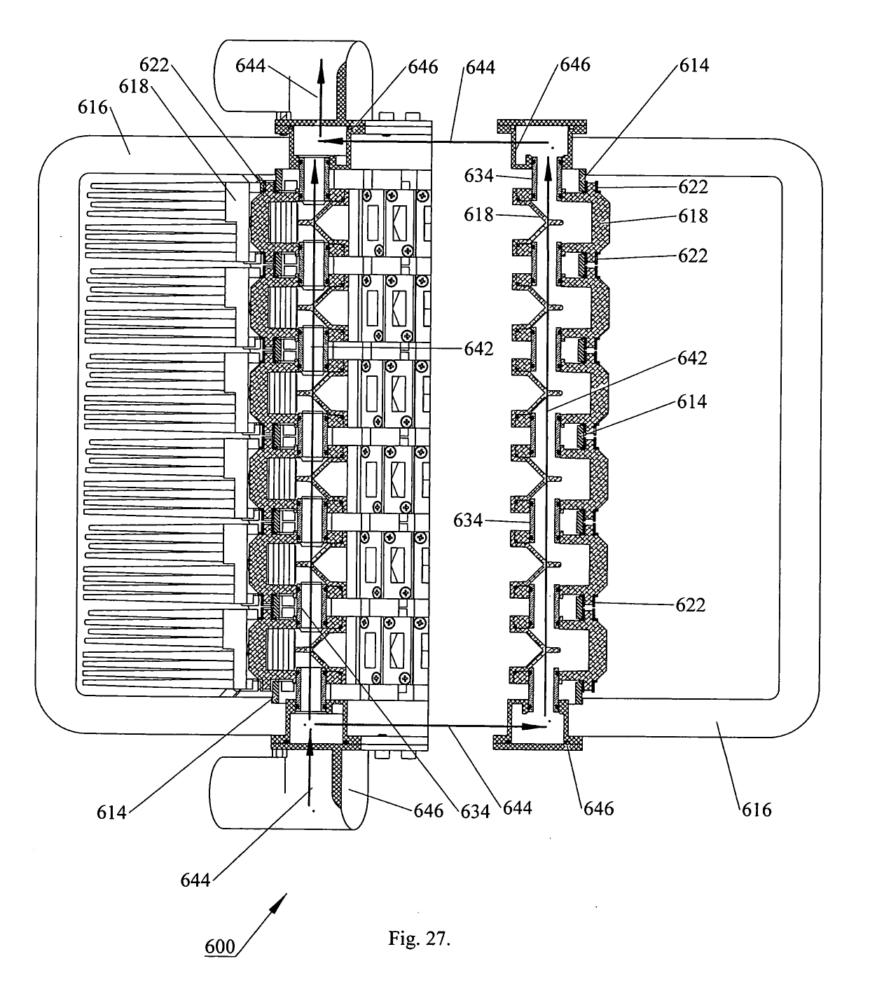

On FIG. 27, arrows 642 show the flow of non-electro conductive liquid in clusters. Arrows 644 show the flow of non-electro conductive liquid in the uniting collectors 646. The device is designed is such a way that the direction of a heat flow can be reversed without losing the functionality of the device, i.e. receiving and giving thermoelectric conductors can swap roles. In this case, the polarity of the generated voltage will reverse. Additionally, the device has a case, an expansion tank, a plug load, an ammeter, a voltmeter, a heat indicator and an overload indicator. Those skilled in the art will appreciate that other components may be used without limiting the scope of the present invention. The components such as the aforementioned case, the expansion tank, the plug load, the ammeter, the voltmeter, the heat indicator and the overload indicator are used here with for exemplary purposes as one of the components to be used without any intent to limit the application of the present invention.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. An apparatus for selectively converting thermal energy to electric energy and transferring heat from one side of said apparatus to the other side of said apparatus with consumption of electric energy, said apparatus comprising:
at least one frame with a plurality of rails forming a plurality of void portions;
a resilient element connected to each of said rails;
a source of fluid supply;
a plurality of collectors for receiving and circulating fluid; and
a plurality of thermoelectric conductors alternating with one another fluidly communicated with said collectors to receive and circulate fluid, said thermoelectric conductors disposed inside said void portions between said rails and presenting a plurality of active devices of different types of conductivity and separated by each of said active devices and with said thermoelectric conductors and said active devices being forced relative to one another by said resilient element and locking said thermoelectric conductors and said active devices within said frame to allow said thermoelectric conductors to expand and contract relative to one another and said collectors thereby extending lifespan of said apparatus.

2. An apparatus as set forth in claim 1, wherein said active devices are further defined by a plurality of active layers and interconnecting layers connected to both surfaces of each of said active layer and sandwiched between each of said active layers and said thermoelectric conductors.

3. An apparatus as set forth in claim 2, wherein said active layers are further defined by layers of N-type conductivity and P-type conductivity alternating with one another wherein said active layers of N-type conductivity are separated by said active layers of P-type conductivity.

4. An apparatus as set forth in claim 3, wherein said interconnecting layers are formed from at least one of deformable substance of electro and thermo conductivity and a solder having a melting temperature point below operating temperature thereby improving effectiveness and extending lifespan of said apparatus wherein said solder transforms between a deformable stage and a solid stage.

5. An apparatus as set forth in claim 4, wherein at least one of said deformable substance and said solder is further defined by a soft paste-like material spreadable along said active layers and connected to said thermoelectric conductors thereby allowing said thermoelectric conductors to expand and contract relative to one another.

6. An apparatus as set forth in claim 1, wherein each of said thermoelectric conductors presents a wedge like configuration having a peripheral surface and a pair of inclined surfaces and a pair of side surfaces.

7. An apparatus as set forth in claim 6, wherein each of said active layers is sandwiched between said inclined surfaces of each of said thermoelectric conductors adjacent one another.

8. An apparatus as set forth in claim 2, wherein each of said active layers presents a core portion surrounded by an elastic element.

9. An apparatus as set forth in claim 2, wherein each of said active layers presents a shape of a washer.

10. An apparatus as set forth in claim 9, wherein each of said washers presents at least one of a circular configuration and a non-circular configuration.

11. An apparatus as set forth in claim 10, wherein each said washers present a thickness being at least three times less than a length.

12. An apparatus as set forth in claim 6, wherein said peripheral surfaces of each of said thermoelectric conductors is further defined by a receiving surface of infrared radiation at one side of said apparatus.

13. An apparatus as set forth in claim 12, wherein said thermoelectric conductors are aligned in a single row presenting a channel inside each of said thermoelectric conductors exchanging heat with non-electro conductive fluid circulated therethrough wherein said channels are defined by a hollow configuration of each wedge with each hollow configuration of each of said wedges being fluidly communicated with one another wherein non-electro conductive fluid directly thermally engages inner surface of each said inclined surfaces and side surfaces of each of said wedges thereby improving effectiveness and extending lifespan of said apparatus.

14. An apparatus as set forth in claim 1, wherein each of said plurality of collectors for receiving and circulating non-electro conductive fluid are connected with each of said thermoelectric conductors and each of said collectors are removably connected with one another.

15. An apparatus as set forth in claim 13, wherein said one side of said apparatus is further defined by heat thermoelectric conductors and the other side is further defined by cold thermoelectric conductors wherein said cold thermoelectric conductors are alternated with said heat thermoelectric conductors thereby defining a cold side of said apparatus and a heat side of said apparatus wherein said hollow configuration of said heat thermoelectric conductors are conjugated with heated non-electro conductive fluid collectors and said hollow configuration of said cold thermoelectric conductors are conjugated with cold non-electro conductive collectors.

16. An apparatus as set forth in claim 1, further including at least one radiator for cooling down cold non-electro conductive liquid, at least one expansion tank, at least one fan, a plug load, an ammeter, a voltmeter, a heat indicator; an overload indicator.

17. A generator for converting thermal energy to electrical energy comprising:
at least one frame with a plurality of rails forming a plurality of void portions;
a resilient element connected to each of said rails;
a source of fluid supply;
a plurality of collectors for receiving and circulating fluid; and
a plurality of thermoelectric conductors of hot and cold types alternating with one another fluidly communicated with said collectors movable with said thermoelectric conductors to receive and circulate fluid, said thermoelectric conductors disposed inside said void portions between said rails and presenting a plurality of active layers of N-type conductivity and P-type conductivity each having a thickness being at least three times less than a length with each of said active layers positioned between and sandwiched by each of said thermoelectric conductors and interconnecting layers formed from at least one of deformable substance of electro and thermo conductivity and a solder having a melting temperature point below operating temperature and spreadable along said active layers and connected to said thermoelectric conductors thereby allowing said thermoelectric conductors to expand and contract relative to one another as said thermoelectric conductors and said active layers and said interconnecting layers are forced relative to one another by said resilient element to lock said thermoelectric conductors within said frame to allow said thermoelectric conductors to expand and contract relative to one another thereby improving effectiveness and extending lifespan of said generator.

18. A generator as set forth in claim 17, wherein said deformable substance is further defined by a soft paste-like material spreadable along said active layers and connected to said thermoelectric conductors thereby allowing said thermoelectric conductors to expand and contract relative to one another.

19. A generator as set forth in claim 17, wherein each of said thermoelectric conductors presents a wedge like configuration having a peripheral surface and a pair of inclined surfaces and a pair of side surfaces.

20. A generator as set forth in claim 19, wherein each of said active layers presents a core portion surrounded by an elastic element.

21. A generator as set forth in claim 20, wherein each of said active layers presents a shape of a washer.

22. A generator as set forth in claim 21, wherein each of said washers presents at least one of a circular configuration and a non-circular configuration.

23. A generator as set forth in claim 22, wherein said peripheral surfaces of each said thermoelectric conductors is further defined by a receiving surface of infrared radiation at one side of said generator.

24. A generator as set forth in claim 23, wherein said thermoelectric conductors are aligned in a single row presenting a channel inside each of said thermoelectric conductors exchanging heat with non-electro conductive fluid circulated therethrough wherein said channels are defined by a hollow construction of each wedge with each hollow configuration of each wedge being fluidly communicated with one another wherein non-electro conductive fluid directly engages inner surface of each said inclined surfaces and side surfaces of each of said wedges.

25. A generator as set forth in claim 17, wherein each of said plurality of collectors for receiving and circulating non-electro conductive fluid are connected with each of said thermoelectric conductors and each of said collectors are removably connected with one another.

26. A generator as set forth in claim 17, wherein said thermoelectric conductors are further defined by heat thermoelectric conductors and cold thermoelectric conductors wherein said cold thermoelectric conductors are alternated with said heat thermoelectric conductors thereby defining a cold side of said generator and a heat side of said generator wherein a hollow configuration of said heat thermoelectric conductors are conjugated with heated non-electro conductive fluid collectors and a hollow configuration of said cold thermoelectric conductors are conjugated with cold non-electro conductive collectors.

27. A method of selectively converting thermal energy to electric energy and transferring heat from one side of an apparatus to the other side of the apparatus for consumption of electric energy, said method comprising the steps of:
forming at least one frame having a plurality of rails cooperable with the frame to form a plurality of void portions;
installing a resilient element connected to each of the rails;
disposing a plurality of hot and cold thermoelectric conductors alternating with one another fluidly communicated with one another and collectors to receive and circulate fluid thereby presenting direct thermal contact between fluid and the plurality of hot and cold thermoelectric conductors;
sandwiching a plurality of active layers of opposite conductivity between the hot and cold thermoelectric conductors; and
sandwiching a plurality of interconnecting layers between each of the active layers and the hot and cold thermoelectric conductors relative to one another and forcing the resilient element against the hot and cold thermoelectric conductors relative to one another thereby locking the hot and cold thermoelectric conductors within the frame to allow the thermoelectric conductors to expand and contract relative to one another to extend lifespan of the apparatus.

28. A method as set forth in claim 27, wherein the step of sandwiching a plurality of interconnecting layers is further defined by forming the interconnecting layers formed from at least one of deformable substance of electro and thermo conductivity and a solder having a melting temperature point below operating temperature.

29. A method as set forth in claim 27, wherein the step of sandwiching the active layers is further defined by forming each of the active layers in a shape of a washer having a thickness of the washer being at least three times less than a length of the washer.

30. A method as set forth in claim 29, including the step of engaging a resilient device around the washer.
